(19) United States
(12) Patent Application Publication
(10) Pub. No.: US 2026/0182339 A1
(43) Pub. Date: Jun. 25, 2026

(54) WIRING STRUCTURE WITH MULTIPLE CONDUCTIVE MATERIALS

(71) Applicant: Samsung Electronics Co., Ltd., Suwon-si (KR)

(72) Inventors: Yeonuk Kim, Suwon-si (KR); Jeongwon Hwang, Suwon-si (KR); Yunho Kang, Suwon-si (KR); Myungho Kong, Suwon-si (KR); Nayoung Lee, Suwon-si (KR)

(21) Appl. No.: 19/426,839

(22) Filed: Dec. 19, 2025

(30) Foreign Application Priority Data
Dec. 24, 2024 (KR) 10-2024-0194839

(51) Int. Cl. H10W 20/42; H10W 20/00; H10W 20/41; H10W 20/44

(52) U.S. Cl. CPC H10W 20/42; H10W 20/036; H10W 20/056; H10W 20/0633; H10W 20/084; H10W 20/425; H10W 20/438; H10W 20/4421; H10W 20/4432

(57) ABSTRACT

A wiring structure may include first to third wirings on a substrate, being spaced apart from each other on the same level and including a first conductive material, first and second vias on the first and second wirings, respectively, and including a second conductive material, a fourth wiring on the first via and including a third conductive material, a third via on the second via and including the third conductive material, a fifth wiring on the third via, being spaced apart from the fourth wiring, and including the third conductive material, a fourth via on the third wiring and including the third conductive material, and a sixth wiring on the fourth via, being spaced apart from the fourth and fifth wirings and including the third conductive material, wherein the first and the fourth vias are on the same level, and the fourth to sixth wirings are on the same level.

### CROSS-REFERENCE TO RELATED APPLICATION

This application claims priority under 35 U.S.C. § 119 to Korean Patent Application No. 10-2024-0194839 filed on Dec. 24, 2024 in the Korean Intellectual Property Office, the entirety of which is hereby incorporated by reference.

### BACKGROUND

Recently, according to the high integration degree of semiconductor devices, distances between adjacent wirings have been decreased, and widths of vias on the wirings have also been decreased. Methods for improving via performance are being developed.

### SUMMARY

Some aspects of the present disclosure provide a wiring structure having improved characteristics.

According to some implementations of the present disclosure, there is a provided a semiconductor device. A wiring structure may include first to third wirings on a substrate, the first to third wirings being spaced apart from each other on the same level, and each of the first to third wirings including a first conductive material, first and second vias on the first and second wirings, respectively, each of the first and second vias including a second conductive material different from the first conductive material, a fourth wiring on the first via, the fourth wiring including a third conductive material different from the first and second conductive materials, a third via on the second via, the third via including the third conductive material, a fifth wiring on the third via, the fifth wiring being spaced apart from the fourth wiring, and the fifth wiring including the third conductive material, a fourth via on the third wiring, the fourth via including the third conductive material and a sixth wiring on the fourth via, the sixth wiring being spaced apart from the fourth and fifth wirings, and the sixth wiring including the third conductive material, wherein the first and the fourth vias are on the same level, wherein the fourth to sixth wirings are on the same level.

According to some implementations of the present disclosure, there is a provided a semiconductor device. A wiring structure may include a first wiring on a substrate, the first wiring extending in a first direction parallel to an upper surface of the substrate, the first wiring having a first width in a second direction parallel to the upper surface of the substrate and crossing the first direction, and the first wiring including a first conductive material, a first via on and in contact with the first wiring, the first via having the first width in the second direction, and the first via including a second conductive material different with the first conductive material, a second via on the first via on the first via, and the second via having a second width in the second direction greater than the first via, and a second wiring on the second via, and the second wiring extending in the second direction. The second via may include a first conductive pattern including a third conductive material different from the first and second conductive materials, and, a first barrier pattern covering a sidewall of the first conductive pattern, and the first barrier pattern including a metal nitride. The second wiring may include, a second conductive pattern including the third conductive material, and a second barrier pattern covering a sidewall and at least a portion of a lower surface of the second conductive pattern, the second barrier pattern being in contact with and connected to the first barrier pattern, and the second barrier including the metal nitride.

According to some implementations of the present disclosure, there is a provided a semiconductor device. A wiring structure may include first to third wirings on a substrate, each of the first to third wirings extending in a first direction parallel to an upper surface of the substrate, the first to third wirings being spaced apart from each other on the same level in a second direction parallel to the upper surface of the substrate and crossing the first direction, and each of the first to third wirings including a first conductive material, first to third hard masks on upper surfaces of the first to third wirings, respectively, each of the first to third hard masks extending in the first direction, a first insulating interlayer pattern on the substrate, the first insulating interlayer pattern covering sidewalls of the first to third wirings and the first to third hard masks, a second insulating interlayer pattern on the first insulating interlayer pattern and the first to third hard masks, a first via including a second conductive material different from the first conductive material, a second via including the second conductive material, the second via extending through the second hard mask and being in contact with the upper surface of the second wiring, a fourth wiring extending in the second direction on the first via and the first insulating interlayer pattern, the fourth wiring including a third conductive material different from the first and second conductive materials, a third via on the second via, the third via including the third conductive material, a fifth wiring extending in the second direction on the third via, the fifth wiring including the third conductive material, a fourth via including a third conductive material, and a sixth wiring on and in contact with the fourth via, the sixth wiring extending in the second direction, and the sixth wiring including the third conductive material. The first via may include a lower portion extending through the first hard mask, the lower portion being in contact with the upper surface of the first wiring, and an upper portion on the lower portion, the upper portion extending through the second insulating interlayer pattern and being in contact with an upper surface of the lower portion, The fourth via may include a lower portion extending through the third hard mask and being in contact with the upper surface of the third wiring, and an upper portion on the lower portion, the upper portion extending through the second insulating interlayer pattern and being in contact with an upper surface of the lower portion of the fourth via.

Some implementations of the wiring structures described herein may include vias with relatively small width and vias with relatively large width. The via with relatively small width are formed to have a single-layered structure, thereby reducing or preventing void formation, and the via with a relatively large width may have a multi-layered structure including the low-resistance metal, thereby reducing their resistance. As a result, the wiring structures including these vias may have improved electrical characteristics.

However, the benefits and features provided by the present disclosure are not limited thereto.

### BRIEF DESCRIPTION OF THE DRAWINGS

FIG. 1 is a plan view illustrating an example of a wiring structure.

FIGS. 2 to 4 are cross-sectional views illustrating the wiring structure of FIG. 1.

FIGS. 5, 9, and 16 are plan views illustrating an example of a method of manufacturing a wiring structure.

FIGS. 6, 7, 8, 10 to 15, and 17 to 28 are cross-sectional views illustrating the example of the method of manufacturing a wiring structure.

FIGS. 29 to 31 are cross-sectional views illustrating an example of a wiring structure.

FIGS. 32 to 34 are cross-sectional views illustrating an example of a method of manufacturing a wiring structure.

### DETAILED DESCRIPTION

It will be understood that, although the terms “first,” “second,” and/or “third” may be used herein to describe various materials, layers (films), regions, electrodes, pads, patterns, structures and processes, these terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of the present disclosure.

Hereinafter, in the specification (and not necessarily in the claims), two directions that are substantially perpendicular to each other among horizontal directions, which are substantially parallel to an upper surface of a substrate, may be referred to as first and second directions D1 and D2, respectively, and a vertical direction substantially perpendicular to the upper surface of the substrate may be referred to as a third direction D3. In some implementations, the first and second directions D1 and D2 may be orthogonal to each other. Each of the first to third directions D1, D2 and D3 may include not only a direction shown in the drawings but also a direction that is opposite thereto.

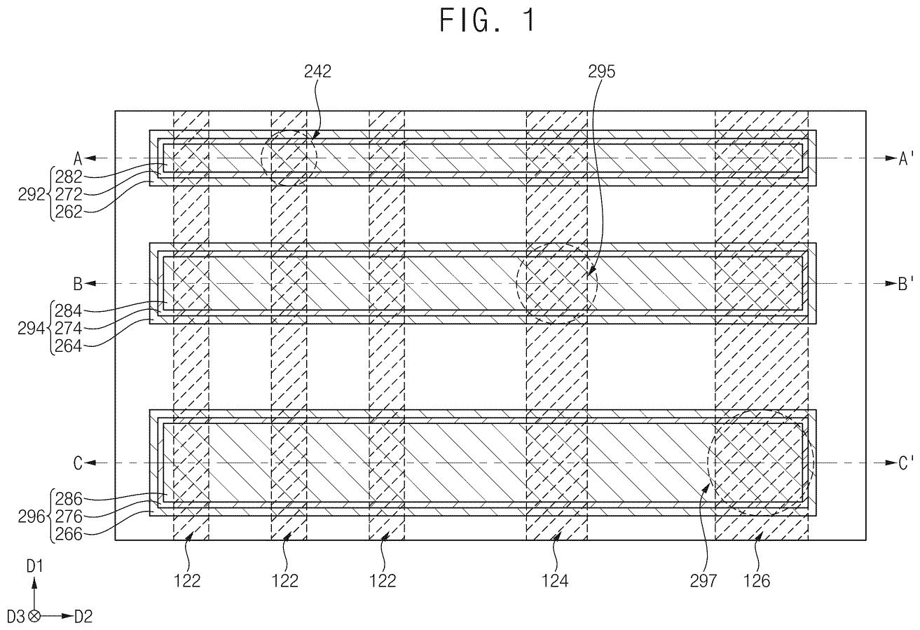

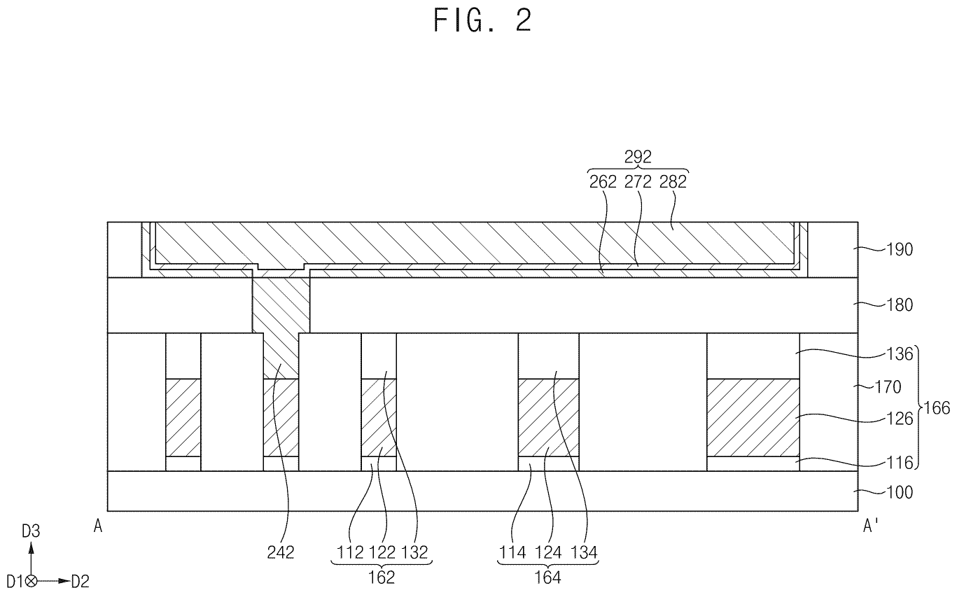

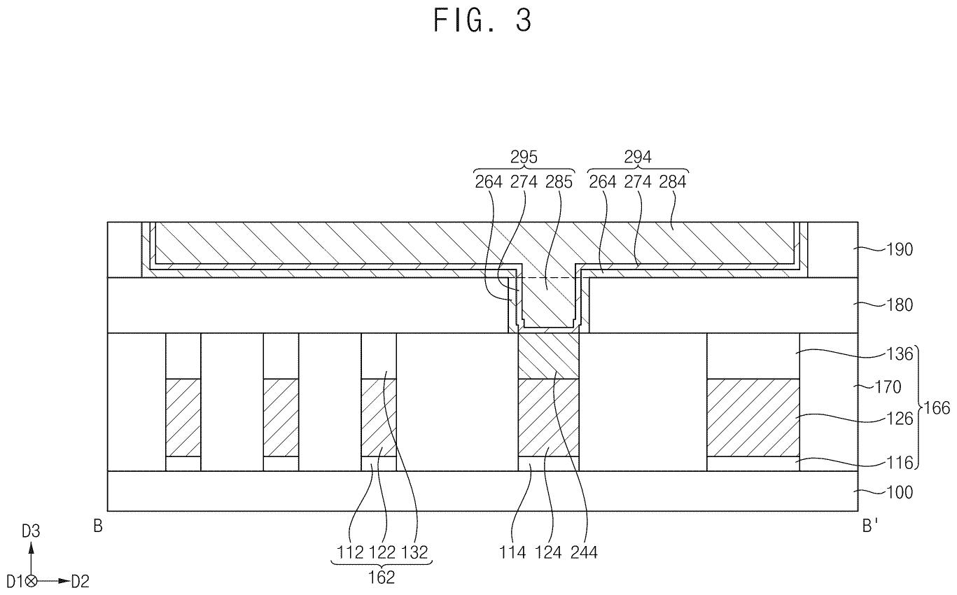

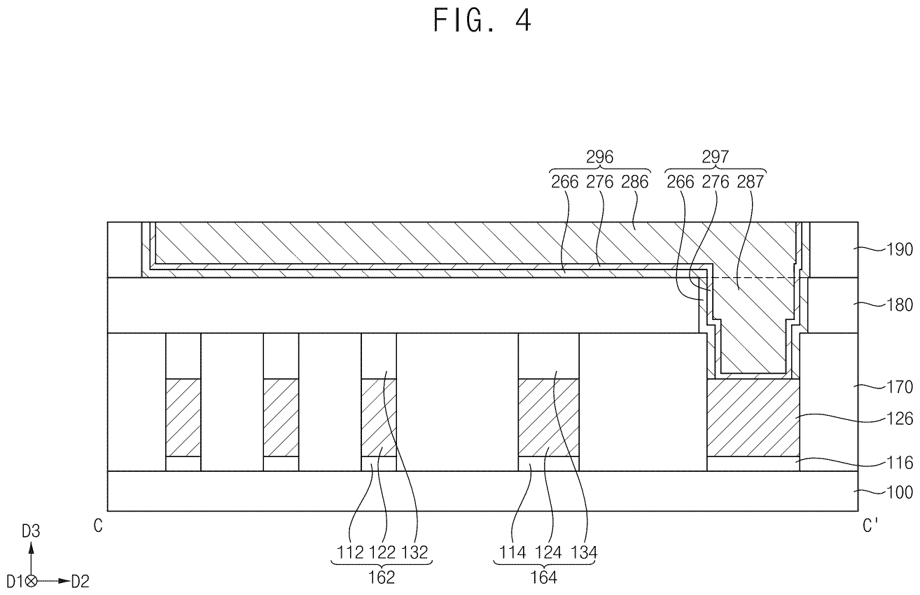

FIGS. 1 to 4 illustrate an example of a wiring structure. Particularly, FIG. 1 is the plan view, FIG. 2 is a cross-sectional view taken along a line A-A′ of FIG. 1, FIG. 3 is a cross-sectional view taken along a line B-B′ of FIG. 1, and FIG. 4 is a cross-sectional view taken along a line C-C′ of FIG. 1.

Referring to FIGS. 1 to 4, the wiring structure may include first to third stacked structures 162, 164 and 166, fourth to sixth wirings 292, 294 and 296, first to fourth vias 242, 244, 295 and 297, and first to third insulating interlayer patterns 170, 180 and 190, which may be disposed on a substrate 100.

The substrate 100 may include, for example, silicon, germanium, silicon-germanium, or a III-V group compound semiconductor, e.g., GaP, GaAs, GaSb, etc. In some implementations, the substrate 100 may be a silicon-on-insulator (SOI) substrate or a germanium-on-insulator (GOI) substrate.

The first to third insulating interlayer patterns 170, 180 and 190 may be sequentially stacked in the third direction D3 on the substrate 100. In some implementations, each of the first to third insulating interlayer patterns 170, 180 and 190 may include an insulating material, e.g., silicon oxycarbide (SiOC), silicon dioxide (SiO₂), silicon nitride (SiN), silicon oxynitride (SiON), silicon carbonitride (SiCN), or silicon oxycarbonitride (SiOCN).

In some implementations, the first insulating interlayer pattern 170 may include a material having a porosity lower than a porosity of each of the second and third insulating interlayer patterns 180 and 190. In some implementations, the second and third insulating interlayer patterns 180 and 190 may include the same insulating material, and thus may be merged with each other. In some implementations, the second and third insulating interlayer patterns 180 and 190 may include different insulating materials, and thus may be differentiated from each other.

The first stacked structure 162 may include a first bonding pattern 112, a first wiring 122, and a first hard mask 132, which may be sequentially stacked in the third direction D3. A lower surface of the first bonding pattern 112 may contact an upper surface of the substrate 100, an upper surface of the first hard mask 132 may contact a lower surface of the second insulating interlayer pattern 180, and a sidewall in the second direction D2 of each of the first bonding pattern 112, the first wiring 122, and the first hard mask 132 may contact a first sidewall of the first insulating interlayer pattern 170. In some implementations, the sidewalls in the second direction D2 of the first bonding pattern 112, the first wiring 122, and the first hard mask 132 may be aligned with each other in the third direction D3.

The second stacked structure 164 may include a second bonding pattern 114, a second wiring 124, and a second hard mask 134, which may be sequentially stacked in the third direction D3. A lower surface of the second bonding pattern 114 may contact the upper surface of the substrate 100, an upper surface of the second hard mask 134 may contact a lower surface of the second insulating interlayer pattern 180, and a sidewall in the second direction D2 of each of the second bonding pattern 114, the second wiring 124, and the second hard mask 134 may contact a second sidewall of the first insulating interlayer pattern 170. In some implementations, the sidewalls in the second direction D2 of the second bonding pattern 114, the second wiring 124, and the second hard mask 134 may be aligned with each other in the third direction D3.

The third stacked structure 166 may include a third bonding pattern 116, a third wiring 126, and a third hard mask 136, which may be sequentially stacked in the third direction D3. A lower surface of the third bonding pattern 116 may contact the upper surface of the substrate 100, an upper surface of the third hard mask 136 may contact a lower surface of the second insulating interlayer pattern 180, and a sidewall of each of the third bonding pattern 116, the third wiring 126, and the third hard mask 136 may contact a third sidewall of the first insulating interlayer pattern 170. In some implementations, the sidewalls in the second direction D2 of the third bonding pattern 116, the third wiring 126, and the third hard mask 136 may be aligned with each other in the third direction D3.

Each of the first to third stacked structures 162, 164 and 166 may extend through the first insulating interlayer pattern 170 in the first direction D1 on the substrate 100, and the first to third stacked structures 162, 164 and 166 may be spaced apart from each other in the second direction D2. The first stacked structure 162 may have a first width in the second direction D2, the second stacked structure 164 may have a second width in the second direction D2 greater than the first width, and the third stacked structure 166 may have a third width in the second direction D2 greater than the second width.

FIGS. 1 to 4 show that three first stacked structure 162, one second stacked structure 164 and one third stacked structure 166 are disposed on the substrate 100, however, the numbers of types of stacked structures and of each type of stacked structure is not limited thereto.

In some implementations, each of the first to third bonding patterns 112, 114 and 116 may include a metal or a metal nitride, e.g., titanium (Ti), titanium nitride (TiN), tantalum (Ta), tantalum nitride (TaN), ruthenium (Ru), etc., each of the first to third wirings 122, 124 and 126 may include a low-resistance metal, e.g., ruthenium (Ru), copper (Cu), tungsten (W), aluminum (Al), molybdenum (Mo), etc., and each of the first to third hard masks 132, 134 and 136 may include an insulating material having a high etching selectivity with respect to the first insulating interlayer pattern 170, e.g., silicon carbonitride (SiCN), silicon nitride (SiN), aluminum oxide (Al₂O₃), aluminum nitride (AlN), hafnium oxide (HfO), zirconium oxide (ZrO), yttrium oxide (Y₂O₃), etc.

The first via 242 may extend through an upper portion of the first insulating interlayer pattern 170, the second insulating interlayer pattern 180, and the first hard mask 132, and may contact an upper surface of the first wiring 122. The first via 242 may include a lower portion and an upper portion stacked in the third direction D3. The lower portion of the first via 242 may have the first width in the second direction D2. The lower portion of the first via 242 may extend through the upper portion of the first insulating interlayer pattern 170 and the first hard mask 132, and may contact the upper surface of the first wiring 122. The upper portion of the first via 242 may have a fourth width in the second direction D2 greater than the first width in the second direction D2. The upper portion of the first via 242 may extend through the second insulating interlayer pattern 180, and may contact an upper surface of the lower portion.

A sidewall in the second direction D2 of the lower portion of the first via 242 may contact an upper portion of the first sidewall of the first insulating interlayer pattern 170, and a sidewall in the first direction D1 of the lower portion of the first via 242 may contact a sidewall in the first direction D1 of the first hard mask 132. The sidewall in the second direction D2 of the lower portion of the first via 242 may be aligned in the first direction D1 with the sidewall in the second direction D2 of the first hard mask 132. Additionally, the sidewall in the second direction D2 of the lower portion of the first via 242 may be aligned in the third direction D3 with the sidewall in the second direction D2 of the first wiring 122. A sidewall of the upper portion of the first via 242 may be surrounded by the second insulating interlayer pattern 180.

The second via 244 may extend through the upper portion of the first insulating interlayer pattern 170 and the second hard mask 134, and may contact an upper surface of the second wiring 124. A sidewall in the second direction D2 of the second via 244 may contact an upper portion of the second sidewall of the first insulating interlayer pattern 170, and a sidewall in the first direction D1 of the second via 244 may contact a sidewall in the first direction D1 of the second hard mask 134. The sidewall in the second direction D2 of the second via 244 may be aligned in the first direction D1 with the sidewall in the second direction D2 of the second hard mask 134, and thus the second via 244 may have the second width in the second direction D2. Additionally, the sidewall in the second direction D2 of the second via 244 may be aligned in the third direction D3 with the sidewall in the second direction D2 of the second wiring 124.

FIGS. 2 and 3 show that the upper surface of the first via 242 is at a height substantially the same as that of the upper surface of the second insulating interlayer pattern 180, and the upper surface of the second via 244 is at a height substantially the same as that of the upper surface of the first insulating interlayer pattern 170. However, the via configuration is not limited thereto. In some implementations, the upper surface of the first via 242 may be higher than the upper surface of the second insulating interlayer pattern 180, and the upper surface of the second via 244 may be higher than the upper surface of the first insulating interlayer pattern 170. The upper surface of the first via 242 may be higher than the upper surface of the second via 244.

In some implementations, each of the first and second vias 242 and 244 may include a first material having a mean free path that is equal to or less than about 10 nm, e.g., ruthenium (Ru), iridium (Ir), etc.

The fourth wiring 292 may be disposed on the second insulating interlayer pattern 180. The fourth wiring 292 may may extend through the third insulating interlayer pattern 190, and may contact the upper surface of the first via 242. A sidewall of the fourth wiring 292 may contact a first sidewall of the third insulating interlayer pattern 190, and a lower surface of the fourth wiring 292 may contact an upper surface of the second insulating interlayer pattern 180 and the upper surface of the first via 242. The fourth wiring 292 may extend in the second direction D2.

The fourth wiring 292 may include a first conductive pattern 282, a first liner 272 covering a sidewall and a lower surface of the first conductive pattern 282, and a first barrier pattern 262 covering a sidewall and a lower surface of the first liner 272. In some implementations, the first barrier pattern 262 may not cover a lower surface of a portion of the first liner 272 disposed on an upper surface of the upper portion of the first via 242. Therefore, the upper surface of the first via 242 may contact the lower surface of the first liner 272, e.g., instead of the first barrier pattern 262.

The third via 295 may extend through the second insulating interlayer pattern 180, and may contact the upper surface of the second via 244. The third via 295 may include a third conductive pattern 285, a second liner 274 covering a sidewall and a lower surface of the third conductive pattern 285, and a second barrier pattern 264 covering a sidewall of the second liner 274. In some implementations, the second barrier pattern 264 may not cover a lower surface of a portion of the second liner 274 disposed on the upper surface of the second via 244. Therefore, the upper surface of the second via 244 may contact the lower surface of the second liner 274, e.g., instead of the second barrier pattern 264. In some implementations, the third via 295 may have a fifth width in the second direction D2, which may be greater than the second and fourth widths.

The fifth wiring 294 may be disposed on the second insulating interlayer pattern 180. The fifth wiring 294 may extend through the third insulating interlayer pattern 190, and may contact an upper surface of the third via 295. A sidewall of the fifth wiring 294 may contact a second sidewall of the third insulating interlayer pattern 190, and a lower surface of the fifth wiring 294 may contact the upper surface of the second insulating interlayer pattern 180 and the upper surface of the third via 295. The fifth wiring 294 may extend in the second direction D2.

The fifth wiring 294 may include a second conductive pattern 284, a second liner 274 covering a sidewall and a lower surface of the second conductive pattern 284, and a second barrier pattern 264 covering a sidewall and a lower surface of the second liner 274. However, the second liner 274 and the second barrier pattern 264 may not be disposed on a lower surface of a portion of the second conductive pattern 284 disposed on the upper surface of the third via 295. Therefore, the upper surface of the third conductive pattern 285 included in the third via 295 may contact the lower surface of the second conductive pattern 284.

In some implementations, the third via 295 and the fifth wiring 294 may be integrally formed. For example, the second and third conductive patterns 284 and 285 may include the same material, and may be in contact with each other such that a boundary therebetween is not distinguishable. The second liner 274 may be continuously disposed on the sidewalls and lower surfaces of the second and third conductive patterns 284 and 285. Furthermore, the second barrier pattern 264 may be continuously disposed on the sidewalls and lower surfaces of the second liner 274. However, the second barrier pattern 264 may not be formed on a lower surface of a portion of the second liner 274 disposed on the upper surface of the second via 244.

The fourth via 297 may extend through the upper portion of the first insulating interlayer pattern 170 and the second insulating interlayer pattern 180, and may contact an upper surface of the third wiring 126. The fourth via 297 may include a lower portion and an upper portion stacked in the third direction D3. The lower portion of the fourth via 297 may have the third width in the second direction D2. The lower portion of the fourth via 297 may extend through the upper portion of the first insulating interlayer pattern 170 and the third hard mask 136, and may contact the upper surface of the third wiring 126. The upper portion of the fourth via 297 may have a sixth width in the second direction D2 greater than the third width in the second direction D2. The upper portion of the fourth via 297 may extend through the second insulating interlayer pattern 180, and may contact an upper surface of the lower portion of the fourth via 297.

A sidewall in the second direction D2 of the lower portion of the fourth via 297 may contact an upper portion of the third sidewall of the first insulating interlayer pattern 170, and a sidewall in the first direction D1 of the lower portion of the fourth via 297 may contact a sidewall in the first direction D1 of the third hard mask 136. The sidewall in the second direction D2 of the lower portion of the fourth via 297 may be aligned in the first direction D1 with the sidewall in the second direction D2 of the third hard mask 136. The sidewall in the second direction D2 of the lower portion of the fourth via 297 may be aligned in the third direction D3 with the sidewall of the third wiring 126 in the second direction D2. A sidewall of the upper portion of the fourth via 297 may be surrounded by the second insulating interlayer pattern 180.

The fourth via 297 may include a fifth conductive pattern 287, a third liner 276 covering a sidewall and a lower surface of the fifth conductive pattern 287, and a third barrier pattern 266 covering a sidewall of the third liner 276. However, the third barrier pattern 266 may not cover a lower surface of a portion of the third liner 276 disposed on the upper surface of the third wiring 126. Therefore, the upper surface of the third wiring 126 may contact a lower surface of the third liner 276, and the third barrier pattern 266 may contact an upper surface of an edge portion of the third wiring 126 in the second direction D2.

The sixth wiring 296 may be disposed on the second insulating interlayer pattern 180. The sixth wiring 296 may extend through the third insulating interlayer pattern 190, and may contact the upper surface of the fourth via 297. A sidewall of the sixth wiring 296 may contact a third sidewall of the third insulating interlayer pattern 190, and a lower surface of the sixth wiring 296 may contact an upper surface of the second insulating interlayer pattern 180 and the upper surface of the fourth via 297. The sixth wiring 296 may extend in the second direction D2.

The sixth wiring 296 may include a fourth conductive pattern 286, a third liner 276 covering a sidewall and a lower surface of the fourth conductive pattern 286, and a third barrier pattern 266 covering a sidewall and a lower surface of the third liner 276. However, the third liner 276 and the third barrier pattern 266 may not be disposed on a lower surface of a portion of the fourth conductive pattern 286 disposed on an upper surface of a fifth conductive pattern 287. Therefore, the upper surface of the fifth conductive pattern 287 included in the fourth via 297 may contact a lower surface of the fourth conductive pattern 286.

In some implementations, the fourth via 297 and the sixth wiring 296 may be integrally formed. For example, the fourth and fifth conductive patterns 286 and 287 may include the same material and may be in contact with each other such that a boundary therebetween is not distinguishable. The third liner 276 may be continuously disposed on sidewalls and lower surfaces of the fourth and fifth conductive patterns 286 and 287. Furthermore, the third barrier pattern 266 may be continuously disposed on sidewalls and lower surfaces of the third liner 276. However, the third barrier pattern 266 may not be formed on a lower surface of a portion of the third liner 276 disposed on the upper surface of the third wiring 126.

In some implementations, the fourth to sixth wirings 292, 294 and 296 may be spaced apart from each other in the first direction D1.

FIG. 1 shows that each of the upper portion of the first via 242, the third via 295, and the fourth via 297 have a circle shape in a plan view, and the upper portion of the first via 242, the third via 295, and the fourth via 297 have the same widths in the first direction D1 as those of the first stacked structure 162, the second stacked structure 164, and the third stacked structure 166, respectively. However, the shapes and sizes are not limited thereto. In some implementations, each of the upper portion of the first via 242, the third via 295, and the fourth via 297 may have other types of shape of, e.g., a shape of an ellipse, a polygon, a polygon with rounded corners, etc., and may have various widths.

Each of the first to fifth conductive patterns 282, 284, 285, 286 and 287 may include, e.g., copper. Each of the first to third liners 272, 274 and 276 may include, e.g., cobalt (Co) or ruthenium (Ru). Each of the first to third barrier patterns 262, 264 and 266 may include a metal nitride, e.g., titanium nitride, tantalum nitride, etc.

As described above with reference to FIGS. 1 to 4, each via with a relatively small width, for example, each of the lower portion of the first via 242 having the first width in the second direction D2, the upper portion of the first via 242 having the fourth width in the second direction D2, and the second via 244 having the second width in the second direction D2 may have a single-layered structure including the first material having the mean free path that is equal to or less than about 10 nm, e.g., ruthenium (Ru), iridium (Ir), etc. each via with a relatively large width, for example, each of the third and fourth vias 295 and 297 may have a multi-layered structure in which the third and fifth conductive patterns 285 and 287 including a low-resistance metal, e.g., copper, the second and third liners 274 and 276 covering surfaces of the third and fifth conductive patterns 285 and 287, and the second and third barrier patterns 264 and 266 covering surfaces of the second and third liners 274 and 276 are stacked.

If the via with a relatively small width has a multi-layered structure, voids or seams may be formed due to a lack of space to arrange a conductive pattern after disposing a barrier pattern and a liner. In contrast, if the via with a relatively large width has a single-layered structure including the first material, the via may have an increased resistance because the first material has a resistance greater than that of the low-resistance metal.

However, in some implementations, the via with a relatively small width may have a single-layered structure including the first material, thereby preventing a void formation. The via with a relatively large width may have a multi-layered structure including the low-resistance metal, thereby reducing a resistance. As a result, the wiring structure including these vias may have improved electrical characteristics.

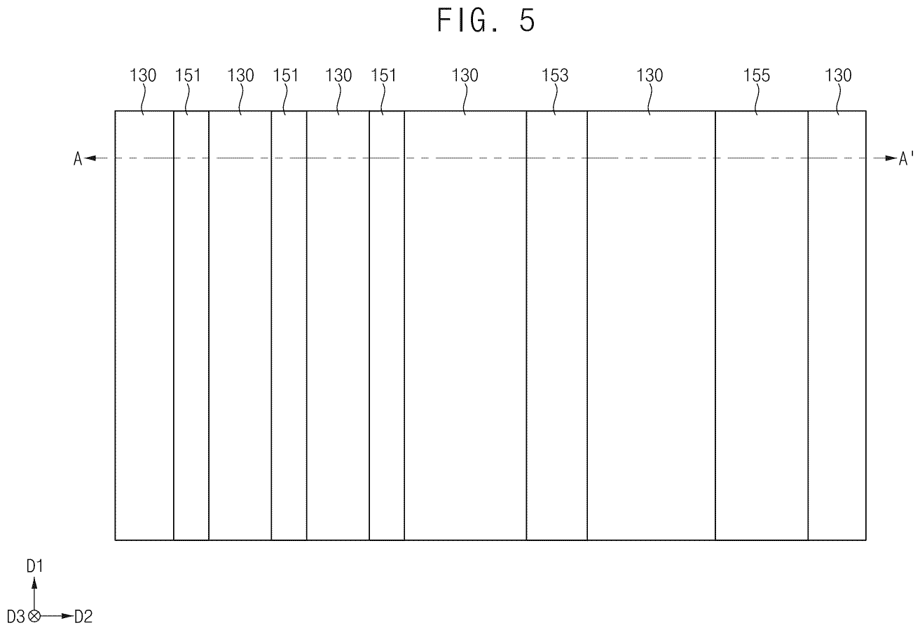

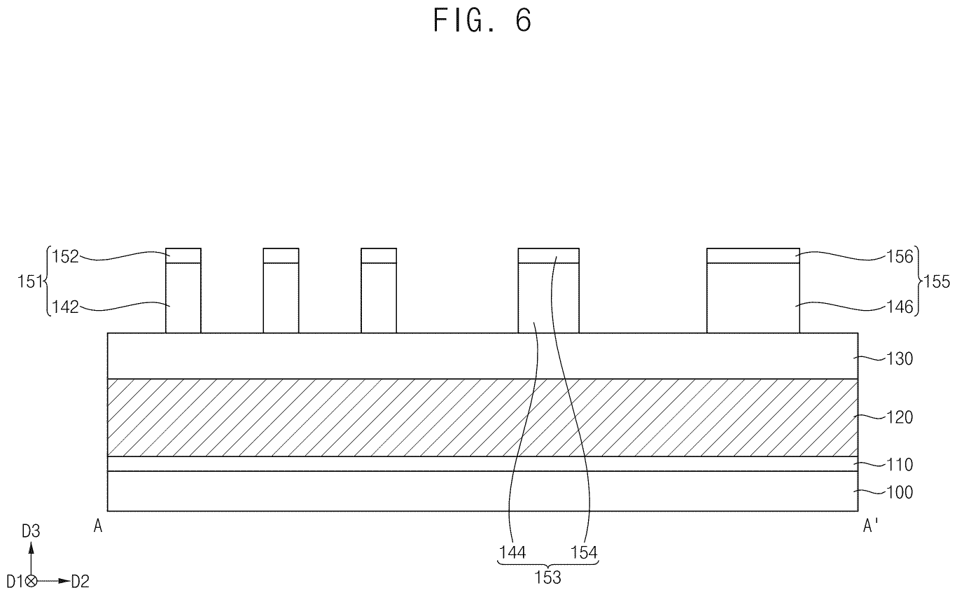

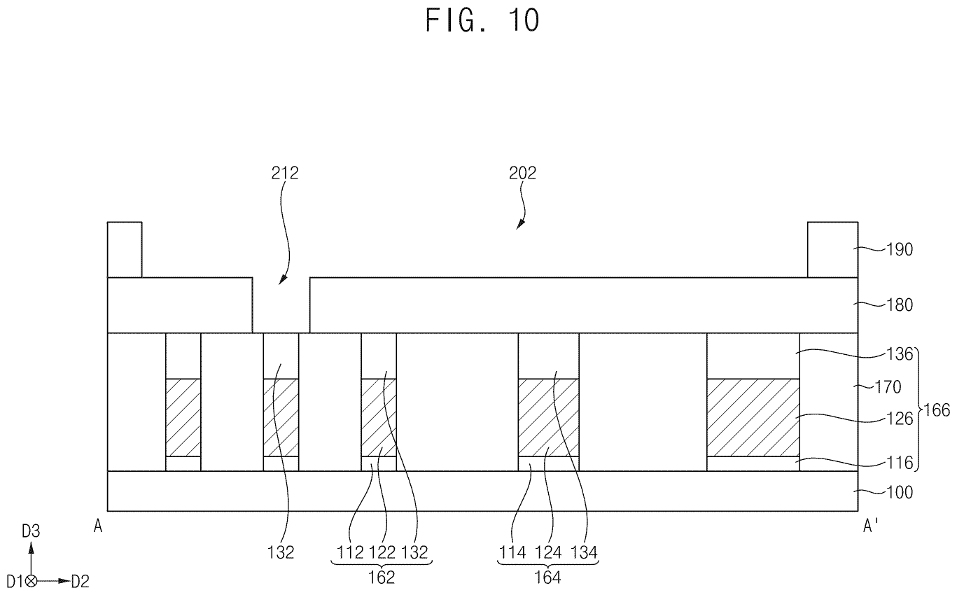

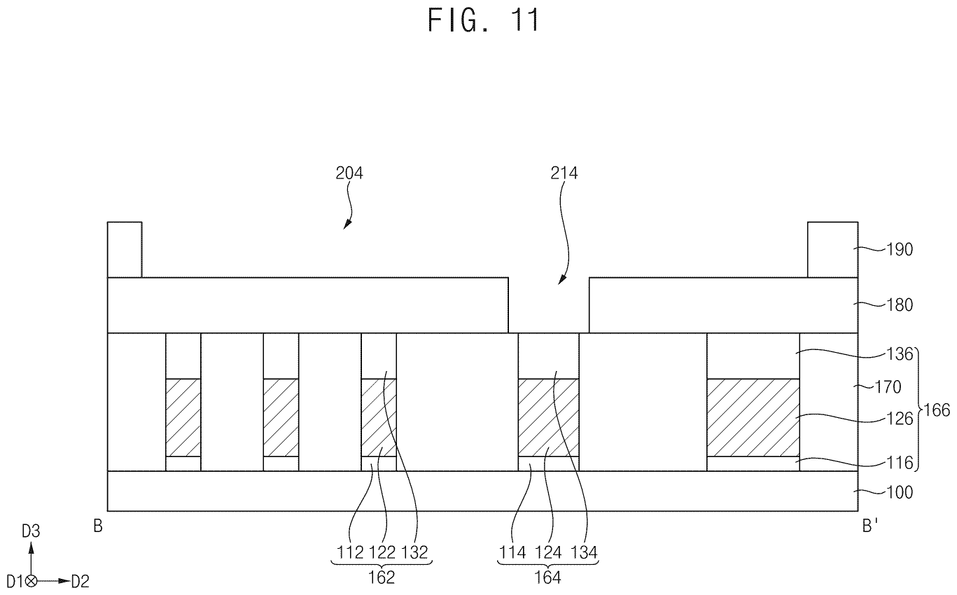

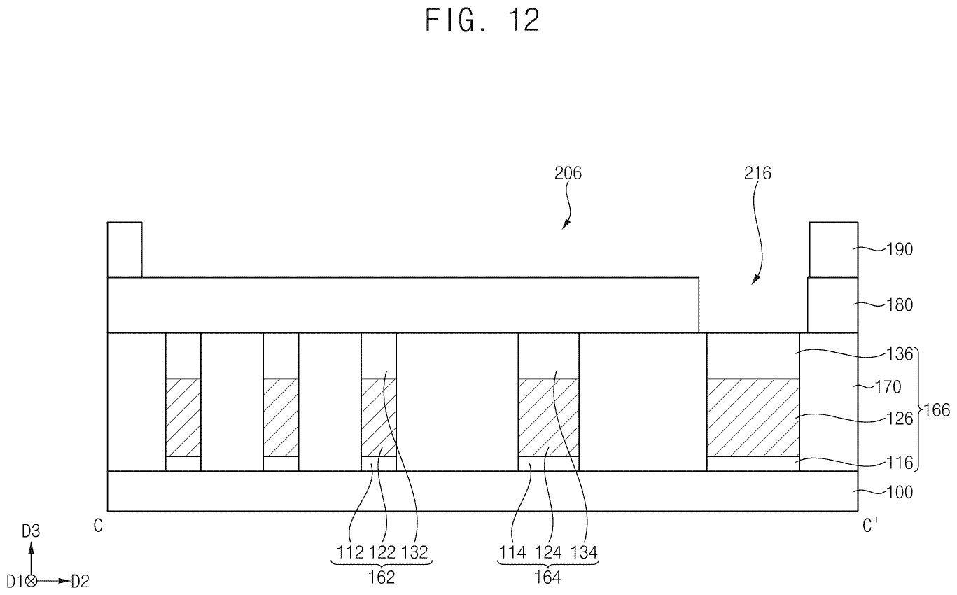

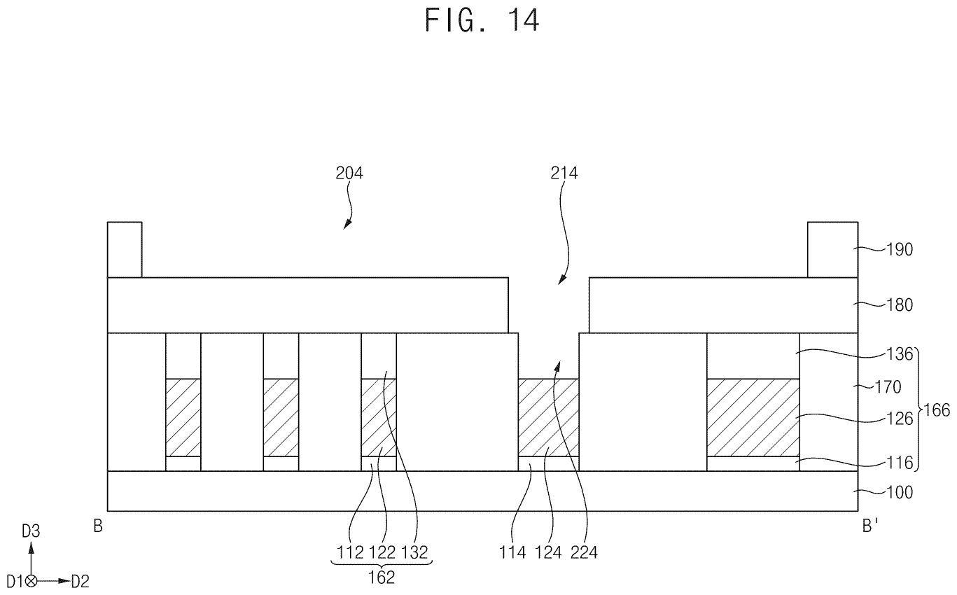

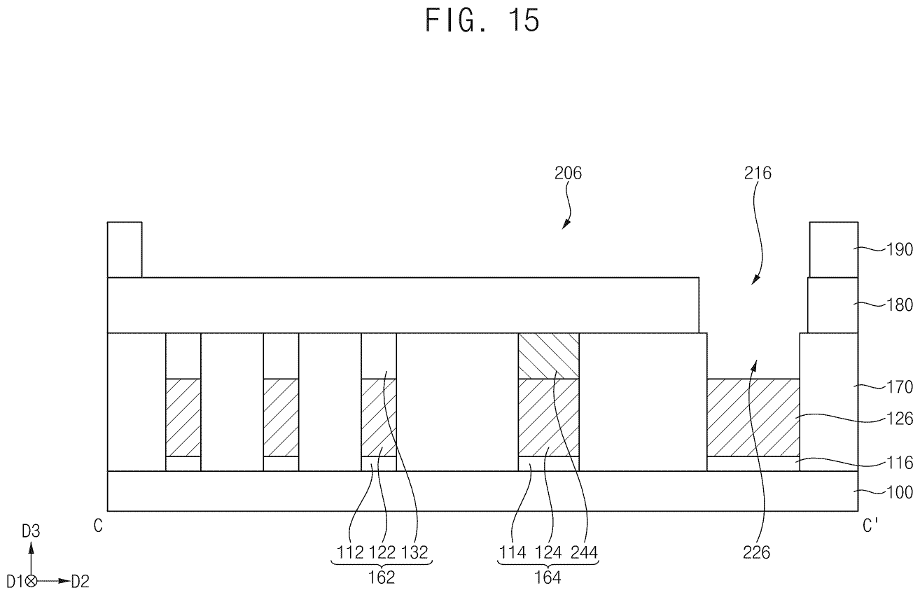

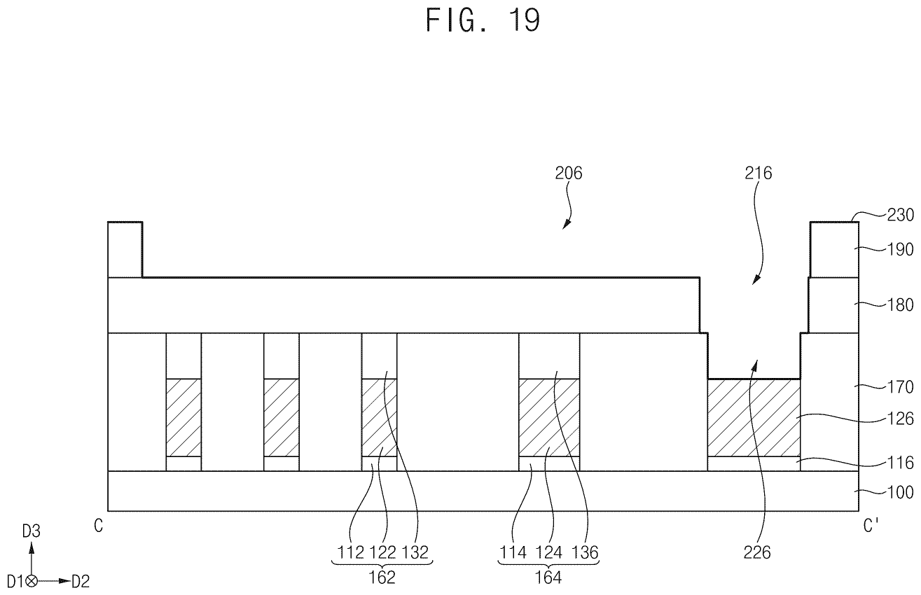

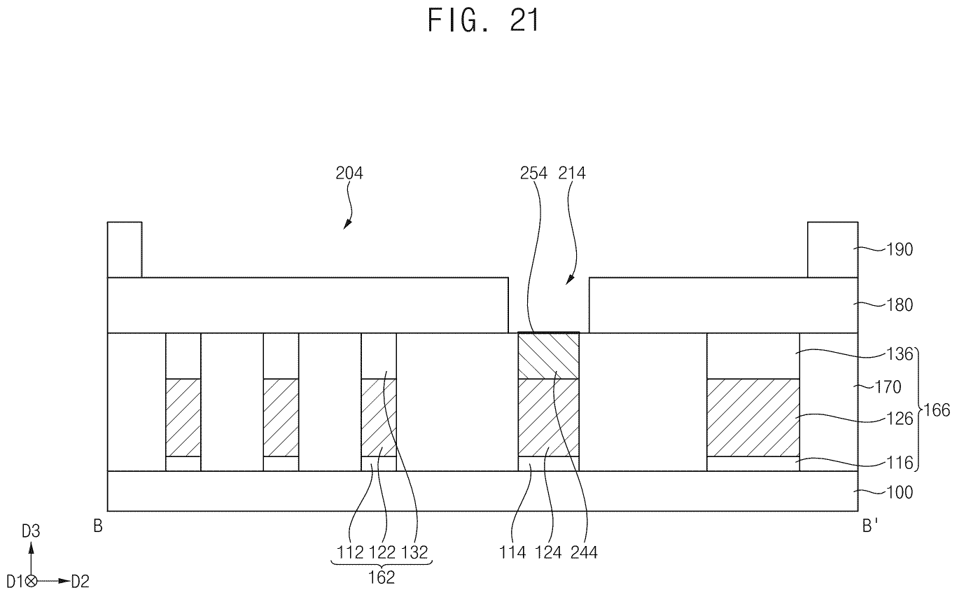

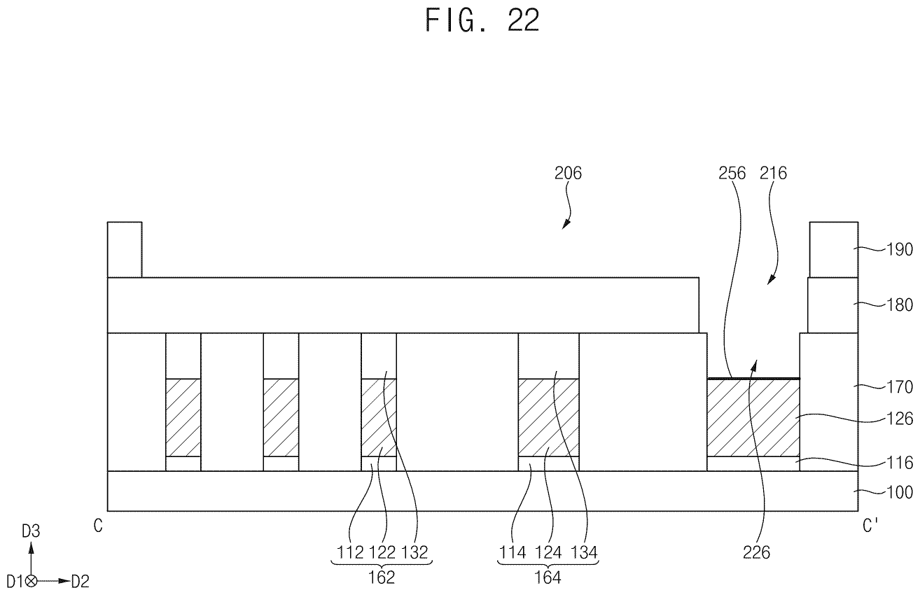

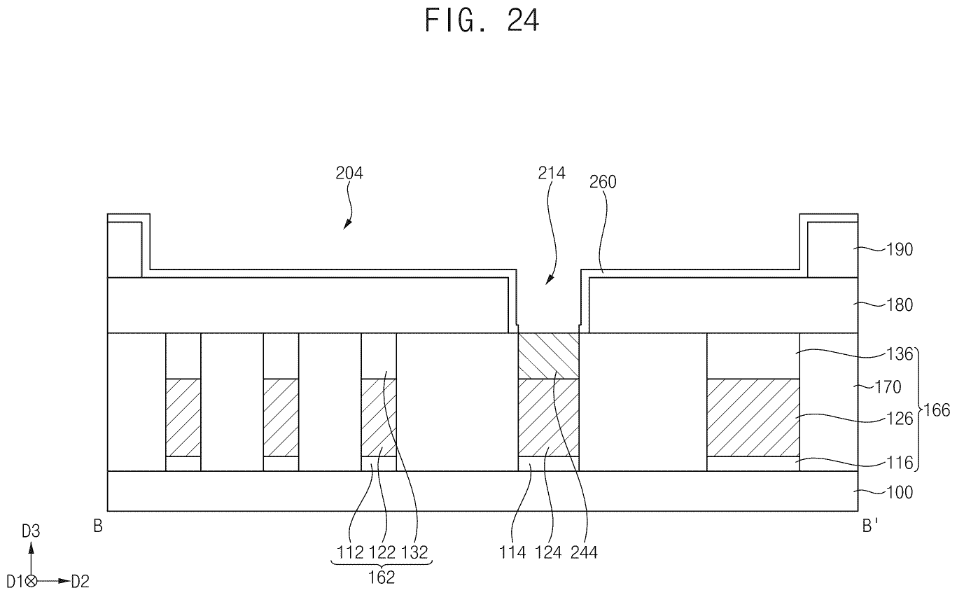

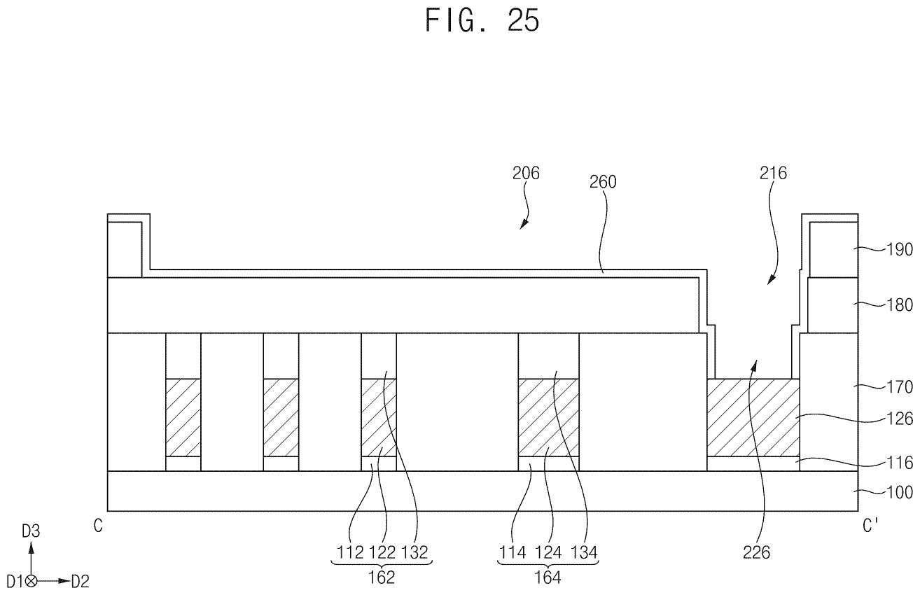

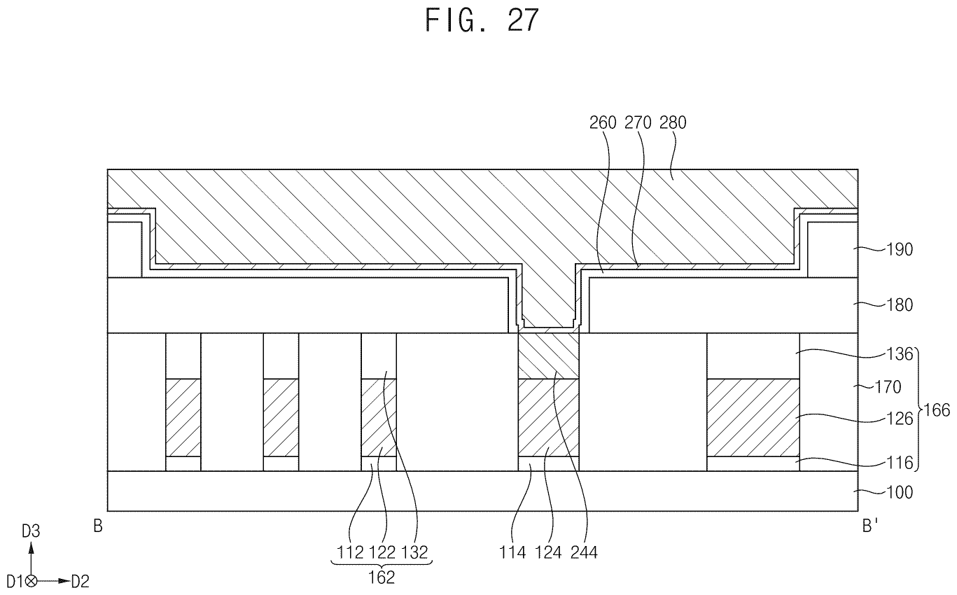

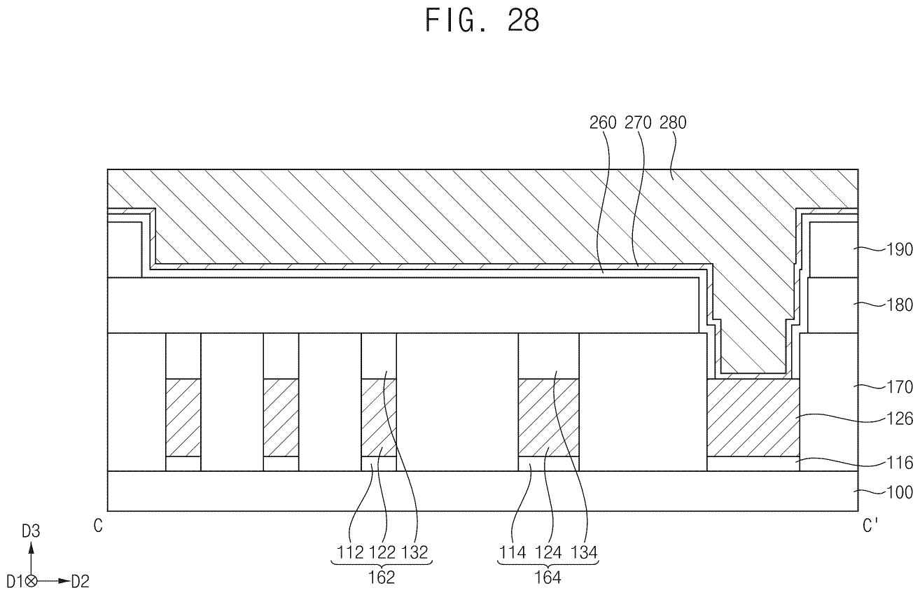

FIGS. 5 to 28 are plan views and cross-sectional views illustrating an example of a method of forming a wiring structure, such as the wiring structure of FIGS. 1 to 4. Particularly, FIGS. 5, 9, and 16 are plan views. FIGS. 6, 7, 8, 10, 13, 17, 20, 23, and 26 are cross-sectional views taken along lines A-A′ of the corresponding plan views, respectively. FIGS. 11, 14, 18, 21, 24, and 27 are cross-sectional views taken along lines B-B′ of the corresponding plan views, respectively. FIGS. 12, 15, 19, 22, 25, and 28 are cross-sectional views taken along lines C-C′ of the corresponding plan views, respectively.

Referring to FIGS. 5 and 6, a bonding layer 110, a first conductive layer 120, a hard mask layer 130, a first mask layer, and a photoresist film may be formed on a substrate 100, the photoresist film may be patterned to form first to third photoresist patterns 152, 154 and 156, and an etching process using the photoresist patterns as an etching mask may be performed to pattern the first mask layer, so that first to third masks 142, 144 and 146, respectively, may be formed.

Therefore, a first mask structure 151 including the first mask 142 and the first photoresist pattern 152 stacked in the third direction D3, a second mask structure 153 including the second mask 144 and the second photoresist pattern 154 stacked in the third direction D3, and a third mask structure 155 including the third mask 146 and the third photoresist pattern 156 stacked in the third direction D3 may be formed.

In some implementations, each of the first to third mask structures 151, 153 and 155 may extend in the first direction D1, and may be spaced apart from each other in the second direction D2. In some implementations, a plurality of first mask structure 151 may be spaced apart from each other in the second direction D2, a plurality of second mask structures 153 may be spaced apart from each other in the second direction D2, and a plurality of third mask structures 155 may be spaced apart from each other in the second direction D2. FIGS. 5 and 6 show that the plurality of first mask structures 151 are spaced apart from each other in the second direction D2.

In some implementations, the first mask structure 151 may have a first width in the second direction D2, the second mask structure 153 may have a second width in the second direction D2 greater than the first width, and the third mask structure 155 may have a third width in the second direction D2 greater than the second width.

The first conductive layer 120 may include a first metal, e.g., ruthenium (Ru), iridium (Ir), copper (Cu), etc.

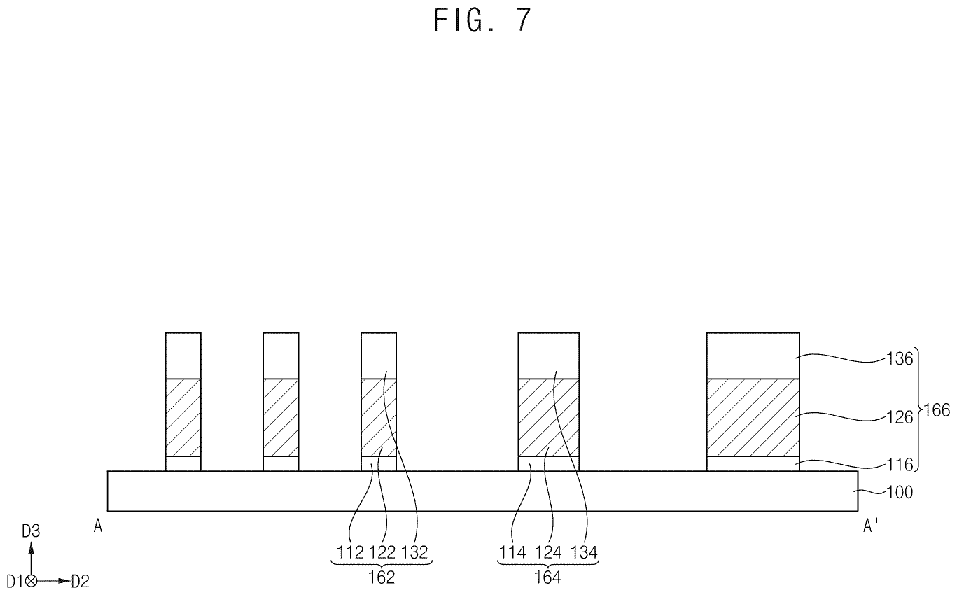

Referring to FIG. 7, an etching process may be performed using the first to third mask structures 151, 153 and 155 as an etching mask to pattern the hard mask layer 130, the first conductive layer 120, and the bonding layer 110.

Therefore, a first bonding pattern 112, a first wiring 122, and a first hard mask 132 may be sequentially stacked in the third direction D3 under the first mask structure 151. A second bonding pattern 114, a second wiring 124, and a second hard mask 134 may be sequentially stacked in the third direction D3 under the second mask structure 153. A third bonding pattern 116, a third wiring 126, and a third hard mask 136 may be sequentially stacked in the third direction D3 under the third mask structure 155.

The first bonding pattern 112, the first wiring 122, and the first hard mask 132 may collectively form a first stacked structure 162, the second bonding pattern 114, the second wiring 124, and the second hard mask 134 may collectively form a second stacked structure 164, and the third bonding pattern 116, the third wiring 126, and the third hard mask 136 may collectively form a third stacked structure 166.

In some implementations, each of the first to third stacked structures 162, 164 and 166 may extend in the first direction D1, and the first to third stacked structures 162, 164 and 166 may be spaced apart from each other in the second direction D2. The first stacked structure 162 may have the first width in the second direction D2, the second stacked structure 164 may have the second width, and the third stacked structure 166 may have the third width in the second direction D2.

The first to third mask structures 151, 153 and 155 may be removed.

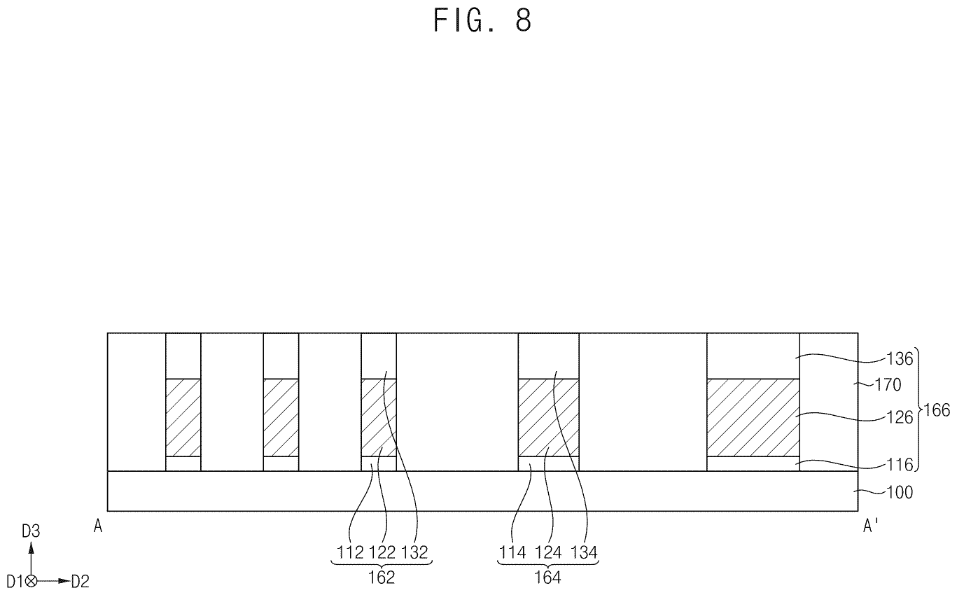

Referring to FIG. 8, a first insulating interlayer may be formed on the substrate 100 to cover the first to third stacked structures 162, 164 and 166, and a planarization process, e.g., a chemical mechanical polishing (CMP) process, may be performed on the first insulating interlayer until upper surfaces of the first to third hard masks 132, 134 and 136 are exposed to form a first insulating interlayer pattern 170.

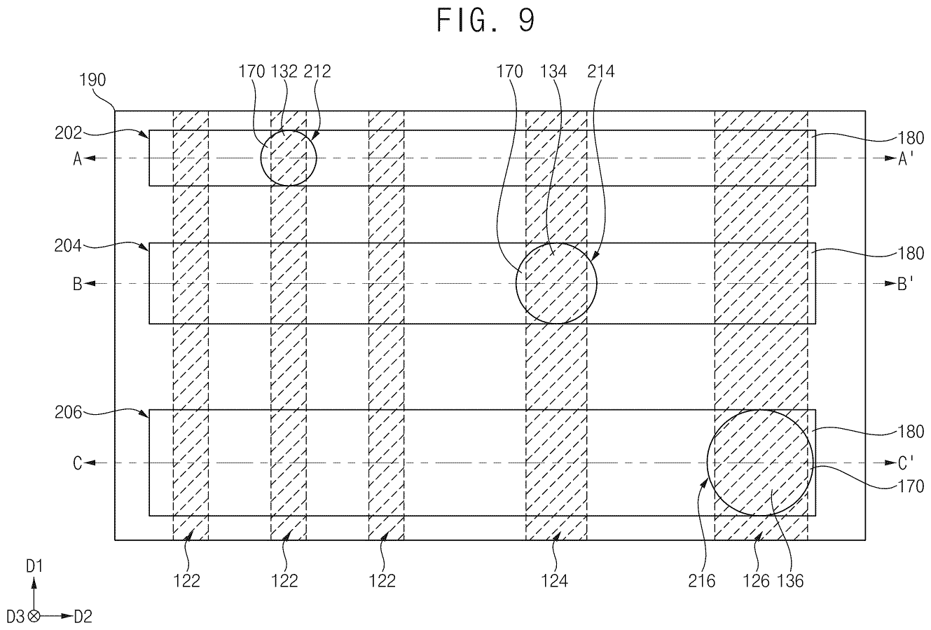

Referring to FIGS. 9 to 12, second and third insulating interlayers may be sequentially formed on the first insulating interlayer pattern 170 and the first to third stacked structures 162, 164 and 166, and an etching process may be performed on the second and third insulating interlayers

Therefore, the second insulating interlayer may be transformed into a second insulating interlayer pattern 180 including a first opening 212 exposing an upper surface of the first hard mask 132, a second opening 214 exposing an upper surface of the second hard mask 134, and a third opening 216 exposing an upper surface of the third hard mask 136. The third insulating interlayer may be transformed into a third insulating interlayer pattern 190 including a first trench 202 connected to the first opening 212, a second trench 204 connected to the second opening 214, and a third trench 206 connected to the third opening 216.

In some implementations, the second and third insulating interlayer patterns 180 and 190 may include the same insulating material and may be merged with each other. In some implementations, the second and third insulating interlayer patterns 180 and 190 may include different insulating materials, and may be distinguished from each other.

In some implementations, the etching process may include a dual damascene process. In a dual damascene process, the third insulating interlayer maybe partially removed to form first to third preliminary openings exposing an upper surface of the second insulating interlayer, an etching mask including fourth to sixth preliminary openings may be formed on the third insulating interlayer, and an etching process using the etching mask may be performed on the second and third insulating interlayers to form the second and third insulating interlayer patterns 180 and 190, respectively. The first to third preliminary openings may be transferred to the first to third openings 212, 214 and 216, respectively, in the second insulating interlayer pattern 180, and the fourth to sixth preliminary openings may be transferred to the first to third trenches 202, 204 and 206, respectively, in the third insulating interlayer pattern 190.

In some implementations, each of the first to third openings 212, 214 and 216 may have a circle shape in a plan view. However, the scope of this disclosure is not limited thereto, and the openings may have other types of shapes of, e.g., a shape of an ellipse, a polygon, a polygon with rounded corners, etc.

The first to third openings 212, 214 and 216 may have fourth to sixth widths, respectively, which may be greater than the first to third widths, respectively. In some implementations, the fourth width may be smaller than the second width.

Each of the first to third trenches 202, 204 and 206 may extend in the second direction D2. FIG. 9 shows that widths in the first direction D1 of the first to third trenches 202, 204 and 206 are substantially the same as widths in the first direction D1 of the first to third openings 212, 214 and 216, respectively, however, the widths are not limited thereto.

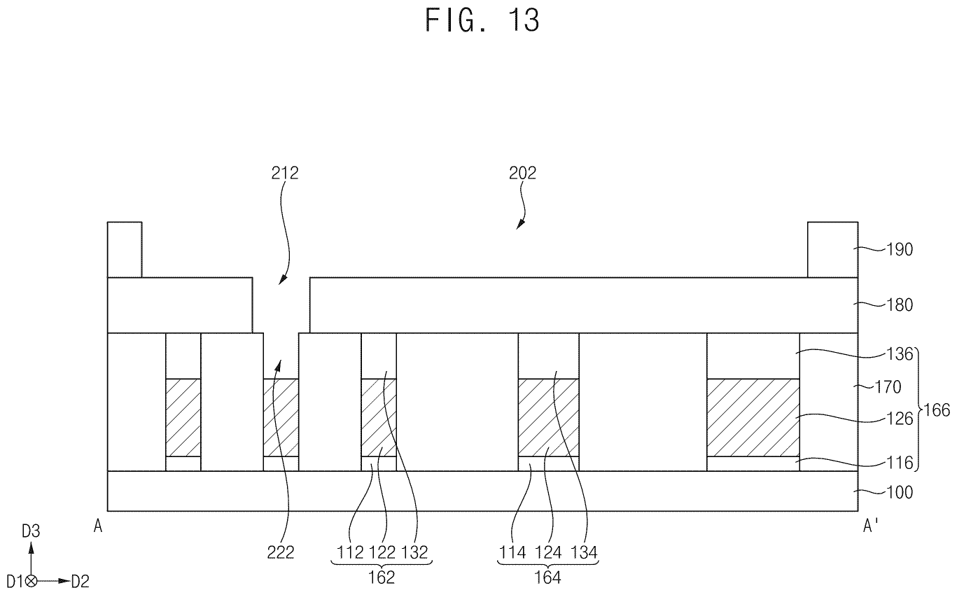

Referring to FIGS. 13 to 15, an etching process may be performed on portions of the first to third hard masks 132, 134 and 136 exposed by the first to third openings 212, 214 and 216 to remove the portions of the first to third hard masks 132, 134 and 136. Therefore, a fourth opening 222 exposing an upper surface of the first wiring 122, a fifth opening 224 exposing an upper surface of the second wiring 124, and a sixth opening 226 exposing an upper surface of the third wiring 126 may be formed.

The fourth to sixth openings 222, 224 and 226 may expose upper portions of first to third sidewalls of the first insulating interlayer pattern 170 adjacent to the first to third wirings 122, 124 and 126, respectively.

The fourth opening 222 may have the first width in the second direction D2, and may be connected to the first opening 212. The fifth opening 224 may have the second width in the second direction D2, and may be connected to the second opening 214. The sixth opening 226 may have the third width in the second direction D2, and may be connected to the third opening 216. The fourth to sixth widths, that is, the widths of the first to third openings 212, 214 and 216 may be greater than the first to third widths, respectively, that is, the widths in the second direction D2 of the fourth to sixth openings 222, 224 and 226, and thus the first to third openings 212, 214 and 216 may expose upper surfaces of the first insulating interlayer pattern 170 adjacent to the first to third wirings 122, 124 and 126, respectively.

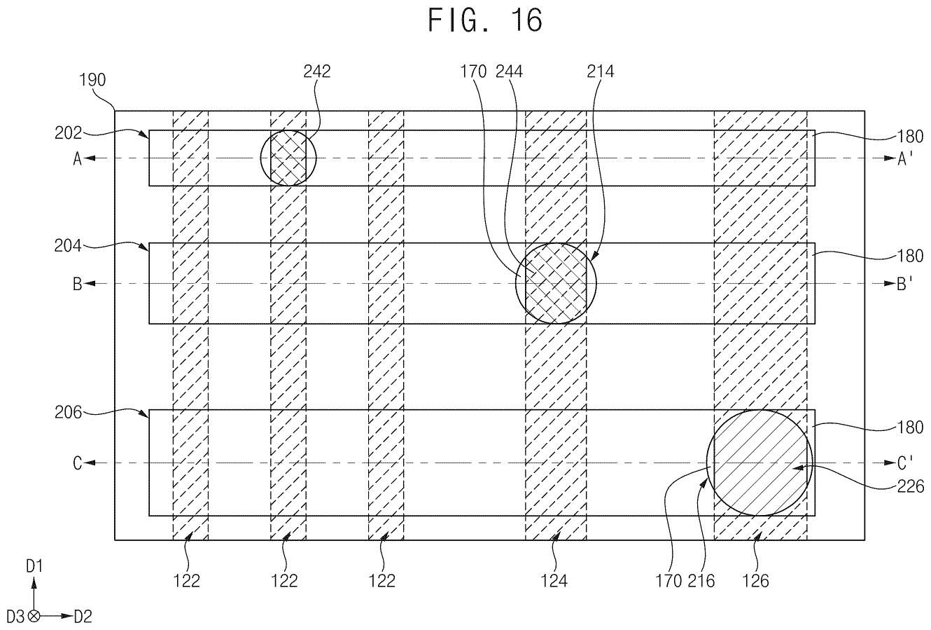

Referring to FIGS. 16 to 19, a deposition process may be performed to form a first via 242 filling the first and fourth openings 212 and 222 on the first wiring 122, and a second via 244 filling the fifth opening 224 on the second wiring 124. Each of the first and second vias 242 and 244 may include a second metal, e.g. ruthenium (Ru).

In some implementations, the deposition process may be performed using a precursor gas of the second metal and a first deposition-blocking gas. The precursor gas of the second metal may diffuse into the first to third trenches 202, 204 and 206, and the first to sixth openings 212, 214, 216, 222, 224 and 226. However, the first deposition-blocking gas may not diffuse into a space having a width, e.g., equal to or less than the second width. Therefore, the first deposition-blocking gas may diffuse into the first to third trenches 202, 204 and 206 and into the second, third and sixth openings 214, 216 and 226, but may not diffuse into the first, fourth and fifth openings 212, 222 and 224 having widths equal to or less than the second width.

Therefore, a deposition-blocking region 230 may be formed on inner walls of the first to third trenches 202, 204 and 206, and the second, third and sixth openings 214, 216 and 226, into which the first deposition-blocking gas diffuses, and the precursor of the second metal may not be deposited or may be deposited only by a very small amount.

The deposition-blocking region 230 may not be formed on the inner walls of the first, fourth and fifth openings 212, 222 and 224, into which the first deposition-blocking gas does not diffuse. Therefore, the precursor of the second metal may be deposited to form the first via 242 in the first and fourth openings 212 and 222 and the second via 244 in the fifth opening 224.

When a small amount of the precursor of the second metal is deposited on the deposition-blocking region 230, e.g., an additional etching process using an etching gas may be performed to remove the precursor of the second metal. In some implementations, the etching process and the deposition process may be sequentially and alternately performed. In some implementations, the etching process and the deposition process may be performed simultaneously, and the precursor gas of the second metal, the first deposition-blocking gas, and the etching gas may be used collectively.

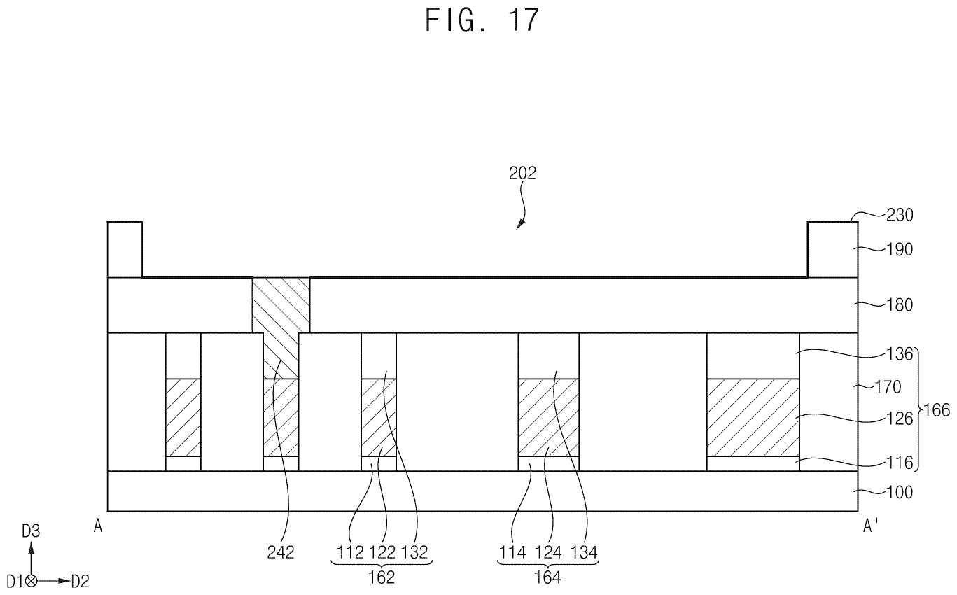

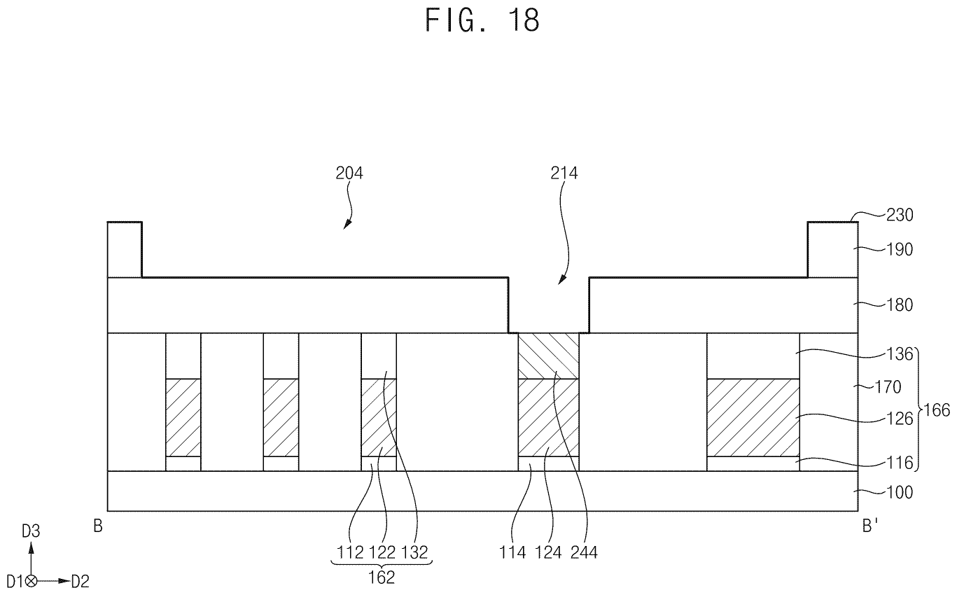

FIGS. 17 and 18 show that an upper surface of the first via 242 is formed at substantially the same height as an upper surface of the second insulating interlayer pattern 180, and an upper surface of the second via 244 is formed at substantially the same height as an upper surface of the first insulating interlayer pattern 170. However, the layer/via configuration is not limited thereto. In some implementations, the upper surface of the first via 242 may be higher than the upper surface of the second insulating interlayer pattern 180, and the upper surface of the second via 244 may be higher than the upper surface of the first insulating interlayer pattern 170.

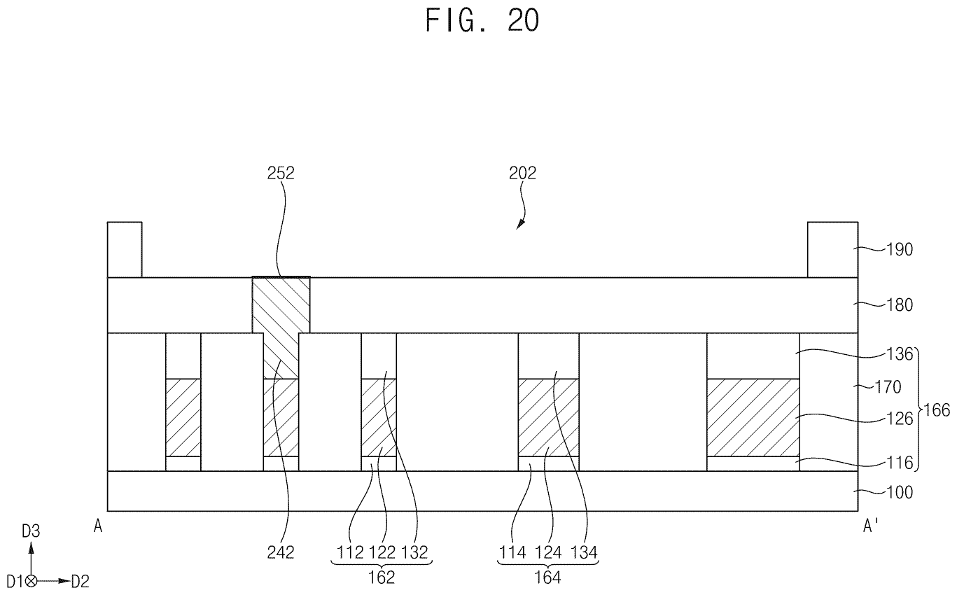

Referring to FIGS. 20 to 22, e.g., a cleaning process may be performed on the upper surfaces of the first and second vias 242 and 244, and on the upper surface of the third wiring 126 exposed by the sixth opening 226 to remove an oxide on the upper surfaces of the first and second vias 242 and 244 and the third wiring 126.

A selective deposition process using a second deposition-blocking gas may be performed to form structures including a metal, for example, first and second deposition-blocking layers 252 and 254 on the upper surfaces of the first and second vias 242 and 244, respectively, and a third deposition-blocking layer 256 on the upper surface of the third wiring 126 exposed by the sixth opening 226.

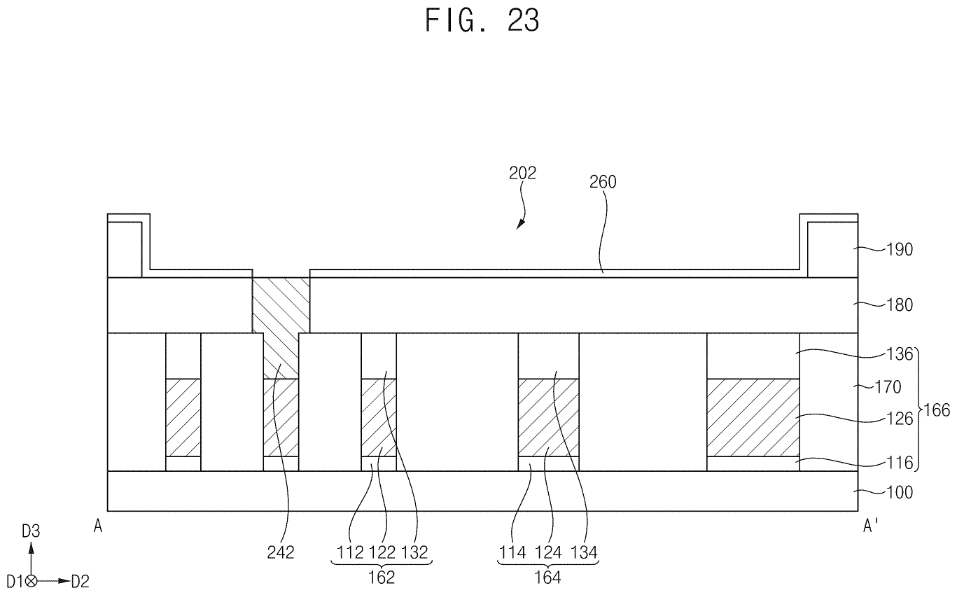

Referring to FIGS. 23 to 25, a barrier layer 260 may be formed on the upper surface and a sidewall of the third insulating interlayer pattern 190, the upper surface and a sidewall of the second insulating interlayer pattern 180, and a sidewall of the first insulating interlayer pattern 170.

The barrier layer 260 may be formed by a deposition process, e.g., an atomic layer deposition (ALD) process or a chemical vapor deposition (CVD) process. The first and second deposition-blocking layers 252 and 254 may be formed on the first and second vias 242 and 244, respectively, and the third deposition-blocking layer 256 may be formed on the third wiring 126, and thus the barrier layer 260 may not be formed on the first to third deposition-blocking layers 252, 254 and 256.

The first to third deposition-blocking layers 252, 254 and 256 may be removed.

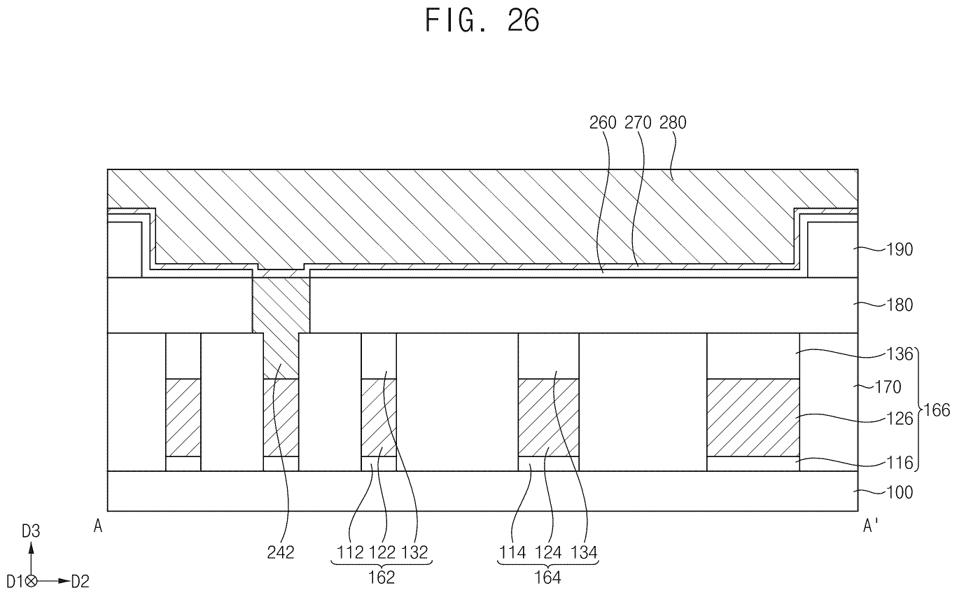

Referring to FIGS. 26 to 28, a liner layer 270 may be formed on the barrier layer 260, the first and second vias 242 and 244, and the third wiring 126, and a second conductive layer 280 may be formed on the liner layer 270 to fill the first to third trenches 202, 204 and 206, and the second, third and sixth openings 214, 216 and 226.

The second conductive layer 280 may be formed by performing a deposition process, e.g., a physical vapor deposition (PVD) process or a chemical vapor deposition (CVD) process to form a preliminary second conductive layer, and performing a reflow process in which a thermal treatment process may be performed on the preliminary second conductive layer at a temperature of about 400° C. to about 600° C. to redistribute the preliminary second conductive layer within the first to third trenches 202, 204 and 206, and the second, third and sixth openings 214, 216 and 226.

In the reflow process, the liner layer 270 may assist the preliminary second conductive layer to be redistributed within the first to third trenches 202, 204 and 206, and the second, third and sixth openings 214, 216 and 226.

Referring to FIGS. 1 to 4 again, e.g., a CMP process may be performed on the second conductive layer 280, the liner layer 270, and the barrier layer 260 until the upper surface of the third insulating interlayer pattern 190 is exposed.

Therefore, the second conductive layer 280 may be divided into a first conductive pattern 282 in the first trench 202, a second conductive pattern 284 in the second trench 204, a third conductive pattern 285 in the second opening 214, a fourth conductive pattern 286 in the third trench 206, and a fifth conductive pattern 287 in the third and sixth openings 216 and 226.

The liner layer 270 may be divided into a first liner 272 in the first trench 202, a second liner 274 in the second trench 204 and the second opening 214, and a third liner 276 in the third trench 206 and the third and sixth openings 216 and 226. The barrier layer 260 may be divided into a first barrier pattern 262 in the first trench 202, a second barrier pattern 264 in the second trench 204 and the second opening 214, and a third barrier pattern 266 in the third trench 206 and the third and sixth openings 216 and 226.

The first barrier pattern 262, the first liner 272, and the first conductive pattern 282 in the first trench 202 may collectively form a fourth wiring 292.

Portions of the second barrier pattern 264, the second liner 274, and the second conductive pattern 284 in the second trench 204 may collectively form a fifth wiring 294. Portions of the second barrier pattern 264, the second liner 274, and the third conductive pattern 285 in the second opening 214 may collectively form a third via 295.1

Furthermore, portions of the third barrier pattern 266, the third liner 276, and the fourth conductive pattern 286 in the third trench 206 may collectively form a sixth wiring 296. Portions of the third barrier pattern 266, the third liner 276, and the fifth conductive pattern 287 in the third and sixth openings 216 and 226 may collectively form a fourth via 297.

As illustrated above, the first to third stacked structures 162, 164 and 166 may be formed on the substrate 100, the fourth to sixth openings 222, 224 and 226 exposing the upper surfaces of the first to third wirings 122, 124 and 126, respectively, may be formed, the first to third openings 212, 214 and 216 connected to the fourth to sixth openings 222, 224 and 226, respectively, may be formed, and the deposition process using both the precursor gas of the second metal and the first deposition-blocking gas may be performed.

In the deposition process, the precursor gas of the second metal may diffuse into the first to sixth openings 212, 214, 216, 222, 224 and 226, while the first deposition-blocking gas may not diffuse into the first, fourth and fifth openings 212, 222 and 224, which may have widths equal to or less than the second width. Therefore, the first via 242 may be formed in the first and fourth openings 212 and 222, and the second via 244 may be formed in the fifth opening 224.

In some cases, if vias having different widths are formed by a deposition process and an etching process, instead of the deposition process using both of the deposition-blocking gas and the metal precursor gas, misalignment may occur between the vias and wirings, causing electrical short circuits or leakage current, and resistances of the vias may increase due to damage caused by the etching process.

However, in accordance with some implementations of the present disclosure, the first and second vias 242 and 244 may be formed to fill the first, fourth and fifth openings 212, 222 and 224 by performing the deposition process without performing the etching process, so that the number of process steps may be reduced, and the misalignment may be prevented.

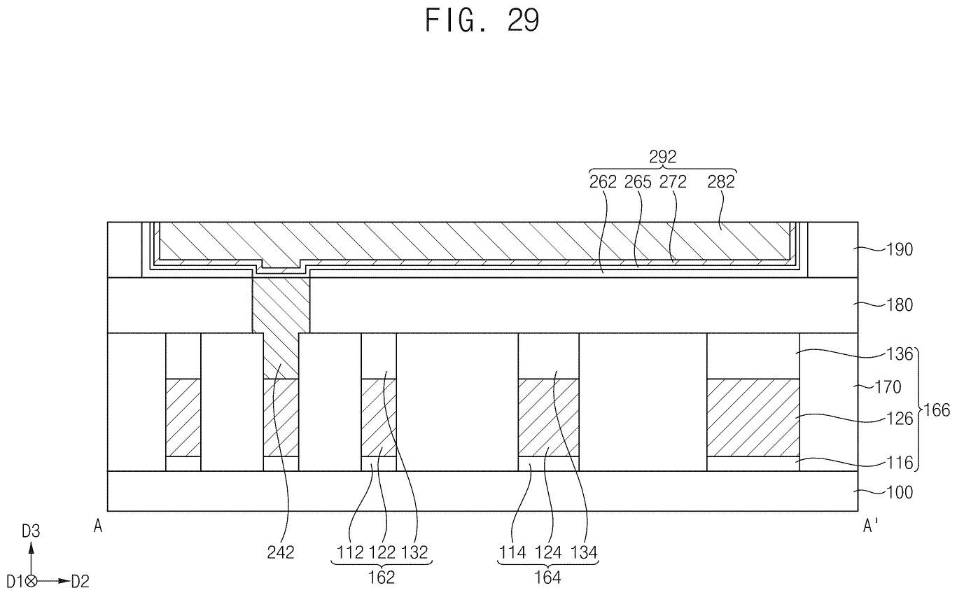

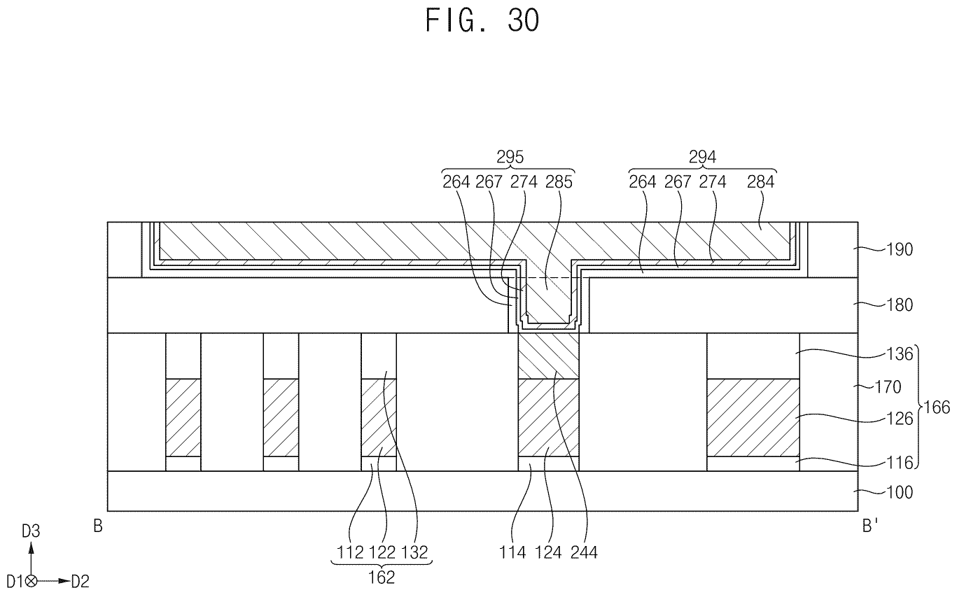

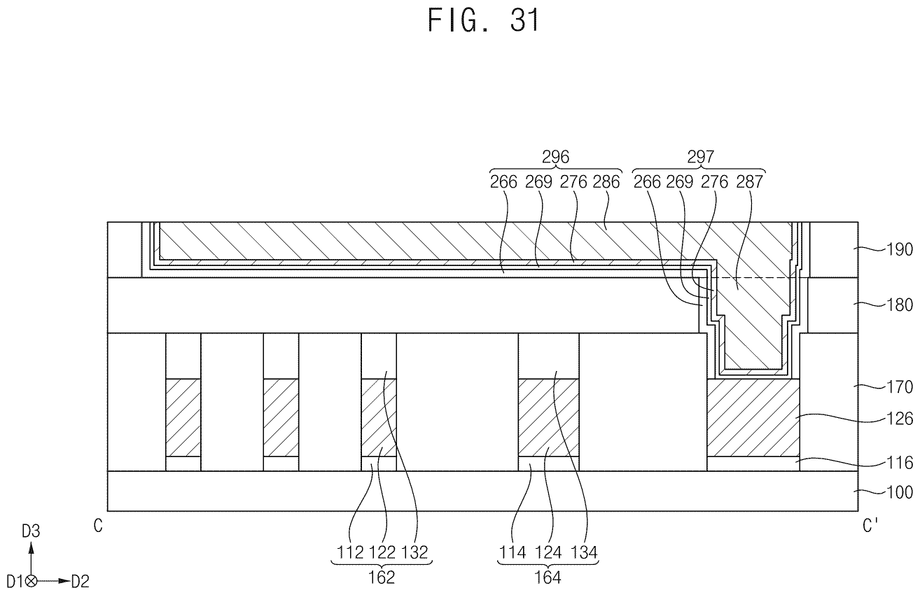

FIGS. 29 to 31 are cross-sectional views illustrating an example of a wiring structure. The views of FIGS. 29 to 31 correspond to the views of which may correspond to FIGS. 2 to 4, respectively.

The wiring structure of FIGS. 29 to 31 may be substantially the same as or similar to that of FIGS. 1 to 4, except for further including fourth to sixth barrier patterns, and thus the same reference numerals are used for the same elements, and repeated explanations thereof are omitted herein.

Referring to FIGS. 29 to 31, the wiring structure may further include a fourth barrier pattern 265 disposed between the first barrier pattern 262 and the first liner 272, a fifth barrier pattern 267 disposed between the second barrier pattern 264 and the second liner 274, and a sixth barrier pattern 269 disposed between the third barrier pattern 266 and the third liner 276.

The fourth barrier pattern 265 may cover a lower surface of a portion of the first liner 272 disposed on the first via 242, the fifth barrier pattern 267 may cover a lower surface of a portion of the second liner 274 disposed on the second via 244, and the sixth barrier pattern 269 may cover a lower surface of a portion of the third liner 276 disposed on the third wiring 126.

Thicknesses of the fourth to sixth barrier patterns 265, 267 and 269 may be substantially half the thicknesses of the first to third barrier patterns 262, 264 and 266, respectively.

In some implementations, each of the fourth to sixth barrier patterns 265, 267 and 269 may include a metal nitride, e.g., titanium nitride, tantalum nitride etc. In some implementations, the fourth to sixth barrier patterns 265, 267 and 269 may include the same material as the first to third barrier patterns 262, 264 and 266, and may be merged therewith.

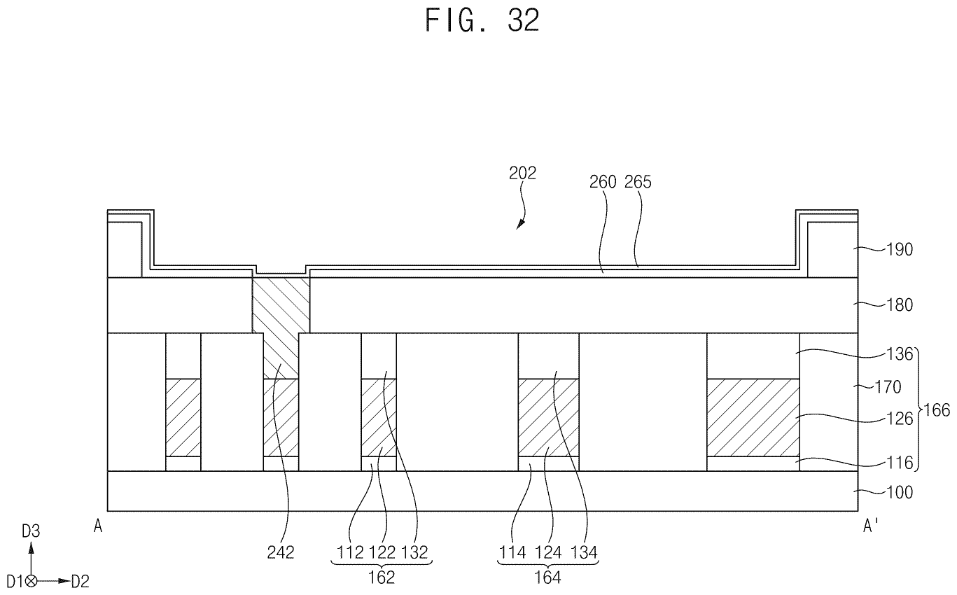

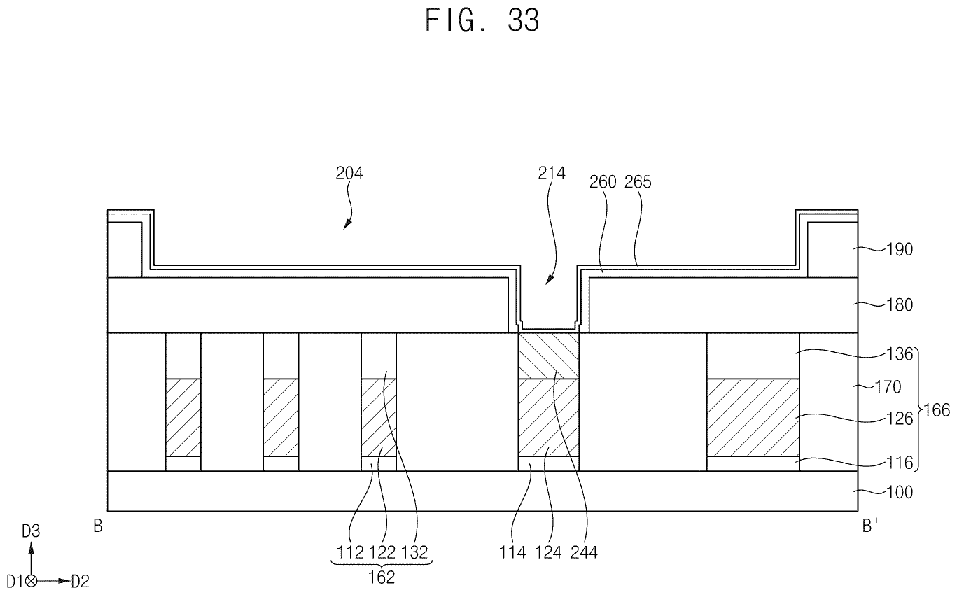

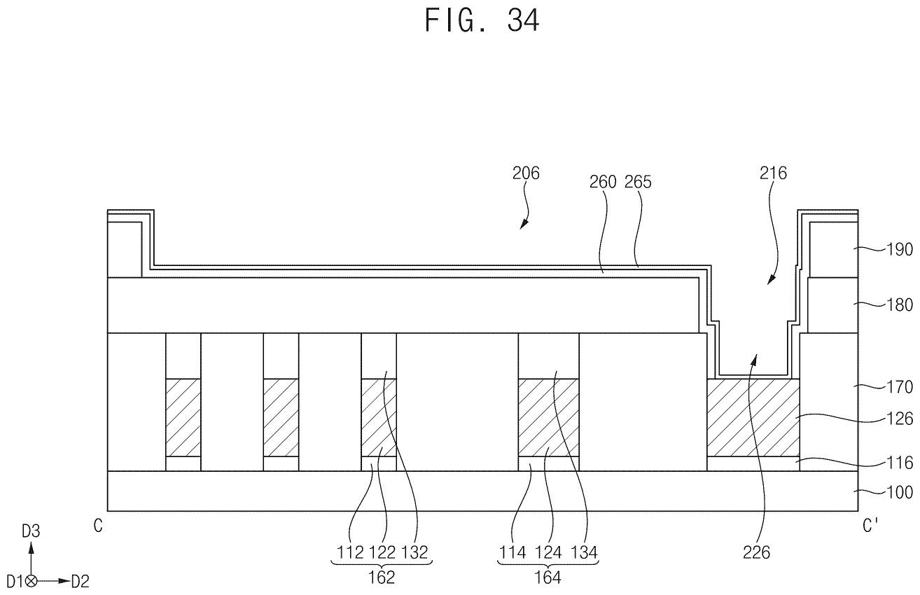

FIGS. 32 to 34 are cross-sectional views illustrating an example of a method of manufacturing a wiring structure, e.g., the wiring structure of FIGS. 29 to 31.

This method may include processes substantially the same as or similar to those illustrated with respect to FIGS. 5 to 31 and FIGS. 1 to 4, and thus repeated explanations are omitted herein.

Referring to FIGS. 32 to 34, processes substantially the same as or similar to those illustrated with respect to FIGS. 5 to 25 may be performed, and the second barrier pattern 264 may be formed on the first barrier pattern 262, the first and second vias 242 and 244, and the portion of the third wiring 126 exposed by the sixth opening 226.

In some implementations, the second barrier pattern 264 may be formed by a deposition process, e.g., a PVD process.

Processes substantially the same as or similar to those illustrated with respect to FIGS. 26 to 28 and FIGS. 1 to 4 may be performed, so that the fabrication of the wiring structure may be completed.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination. Described operations may be performed in a different order from that described or illustrated in the drawings.

While implementations according to the present disclosure have been particularly shown and described with reference to examples thereof, it will be understood that various changes in form and details may be made therein without departing from the spirit and scope of the following claims.

What is claimed is:

1. A wiring structure comprising:
a first wiring, a second wiring, and a third wiring on a substrate at a same first vertical level, the first to third wirings spaced apart from each other, wherein each of the first to third wirings includes a first conductive material;
first and second vias on the first and second wirings, respectively, each of the first and second vias including a second conductive material different from the first conductive material;
a fourth wiring on the first via, the fourth wiring including a third conductive material different from the first and second conductive materials;
a third via on the second via, the third via including the third conductive material;
a fifth wiring on the third via, the fifth wiring spaced apart from the fourth wiring, wherein the fifth wiring includes the third conductive material;
a fourth via on the third wiring, the fourth via including the third conductive material; and
a sixth wiring on the fourth via, the sixth wiring spaced apart from the fourth and fifth wirings, wherein the sixth wiring includes the third conductive material,
wherein the first and the fourth vias are at a same second vertical level, and
wherein the fourth to sixth wirings are at a same third vertical level.

2. The wiring structure of claim 1, wherein:
the second conductive material includes ruthenium or iridium, and
the third conductive material includes copper.

3. The wiring structure of claim 1, wherein:
each of the first to third wirings extends in a first direction parallel to an upper surface of the substrate, the first to third wirings spaced apart from each other in a second direction parallel to the upper surface of the substrate and crossing the first direction,
the first wiring has a first width in the second direction,
the second wiring has a second width in the second direction, wherein the second width is greater than the first width, and
the third wiring has a third width in the second direction, wherein the third width is greater than the second width.

4. The wiring structure of claim 3, wherein the first via includes:
a lower portion having the first width in the second direction; and
an upper portion on the lower portion, the upper portion having a fourth width in the second direction, wherein the fourth width is greater than the first width.

5. The wiring structure of claim 4, wherein:
the second via has the second width in the second direction, and
the third via has a fifth width in the second direction, wherein the fifth width is greater than the second and fourth widths.

6. The wiring structure of claim 4, wherein:
the second via is at a same vertical level as the lower portion of the first via, and
the third via is at a same vertical level as the upper portion of the first via.

7. The wiring structure of claim 3, wherein the fourth via includes:
a lower portion having the third width in the second direction; and
an upper portion on the lower portion, wherein the upper portion has a fifth width in the second direction, and wherein the fifth width is greater than the third width.

8. The wiring structure of claim 1, wherein:
the fourth wiring includes a first conductive pattern including the third conductive material, and a first barrier pattern covering a sidewall and at least a portion of a lower surface of the first conductive pattern,
the fifth wiring includes a second conductive pattern including the third conductive material, and a second barrier pattern covering a sidewall and at least a portion of a lower surface of the second conductive pattern,
the sixth wiring includes a third conductive pattern including the third conductive material, and a third barrier pattern covering a sidewall and at least a portion of a lower surface of the third conductive pattern.

9. The wiring structure of claim 8, wherein:
the third via includes a fourth conductive pattern including the third conductive material, and a fourth barrier pattern covering a sidewall of the fourth conductive pattern,
the fourth via includes a fifth conductive pattern including the third conductive material, and a fifth barrier pattern covering a sidewall of the fifth conductive pattern,
the fourth barrier pattern is in contact with the second barrier pattern, and
the fifth barrier pattern is in contact with the third barrier pattern.

10. The wiring structure of claim 9, wherein:
the fourth wiring further includes a first liner between the third conductive pattern and the third barrier pattern,
the third via further includes a second liner between the fourth conductive pattern and the fourth barrier pattern, and
the fourth via further includes a third liner between the fifth conductive pattern and the fifth barrier pattern.

11. The wiring structure of claim 10, wherein:
an upper surface of the first via is in contact with a lower surface of the first liner,
an upper surface of the second via is in contact with a lower surface of the second liner,
an upper surface of the third via is in contact with a lower surface of the third liner, and
each of the first to third liners includes a metal nitride.

12. The wiring structure of claim 10, wherein:
the fourth wiring further includes a sixth barrier pattern between the first liner and the third barrier pattern,
the third via further includes a seventh barrier pattern between the second liner and the fourth barrier pattern,
the fourth via further includes an eighth barrier pattern between the third liner and the fifth barrier pattern, and
upper surfaces of the first via, the second via, and the third wiring are in contact with lower surfaces of the sixth barrier pattern, the seventh barrier pattern, and the eighth barrier pattern, respectively.

13. A wiring structure comprising:
a first wiring on a substrate, the first wiring extending in a first direction parallel to an upper surface of the substrate, the first wiring having a first width in a second direction parallel to the upper surface of the substrate and crossing the first direction, and the first wiring including a first conductive material;
a first via on and in contact with the first wiring, the first via having the first width in the second direction, wherein the first via includes a second conductive material different from the first conductive material;
a second via on the first via, the second via having a second width in the second direction greater than the first via, wherein the second via comprises:
a first conductive pattern including a third conductive material different from the first and second conductive materials, and
a first barrier pattern covering a sidewall of the first conductive pattern, wherein the first barrier pattern includes a metal nitride; and
a second wiring on the second via, the second wiring extending in the second direction, wherein the second wiring comprises:
a second conductive pattern including the third conductive material; and
a second barrier pattern covering a sidewall and at least a portion of a lower surface of the second conductive pattern, wherein the second barrier pattern is in contact with the first barrier pattern, and wherein the second barrier pattern includes the metal nitride.

14. The wiring structure of claim 13, wherein:
the second via further includes a liner between the first barrier pattern and the first conductive pattern, and
an upper surface of the first via is in contact with a lower surface of the liner.

15. The wiring structure of claim 14, wherein:
the second conductive material includes ruthenium or iridium,
the third conductive material includes copper,
the metal nitride includes titanium nitride or tantalum nitride, and
the liner includes cobalt or ruthenium.

16. The wiring structure of claim 13, wherein:
the second via further includes a third barrier pattern and a liner between the first barrier pattern and the first conductive pattern, and
an upper surface of the first via is in contact with a lower surface of the liner.

17. A wiring structure comprising:
a first wiring, a second wiring, and a third wiring at a same vertical level on a substrate, each of the first to third wirings extending in a first direction parallel to an upper surface of the substrate, the first to third wirings being spaced apart from each other in a second direction parallel to the upper surface of the substrate and crossing the first direction, wherein each of the first to third wirings includes a first conductive material;
a first hard mask, a second hard mask, and a third hard mask on upper surfaces of the first wiring, the second wiring, and the third wiring, respectively, each of the first to third hard masks extending in the first direction;
a first insulating interlayer pattern on the substrate, the first insulating interlayer pattern covering sidewalls of the first to third wirings and the first to third hard masks;
a second insulating interlayer pattern on the first insulating interlayer pattern and the first to third hard masks;
a first via including a second conductive material different from the first conductive material, wherein the first via comprises:
a lower portion extending through the first hard mask, wherein the lower portion of the first via is in contact with the upper surface of the first wiring, and
an upper portion on the lower portion of the first via, the upper portion of the first via extending through the second insulating interlayer pattern and in contact with an upper surface of the lower portion of the first via;
a second via including the second conductive material, the second via extending through the second hard mask and in contact with the upper surface of the second wiring;
a fourth wiring extending in the second direction on the first via and the first insulating interlayer pattern, the fourth wiring including a third conductive material different from the first and second conductive materials;
a third via on the second via, the third via including the third conductive material;
a fifth wiring extending in the second direction on the third via, the fifth wiring including the third conductive material;
a fourth via including the third conductive material, the fourth via comprising:
a lower portion extending through the third hard mask and in contact with the upper surface of the third wiring; and
an upper portion on the lower portion of the fourth via, the upper portion of the fourth via extending through the second insulating interlayer pattern and in contact with an upper surface of the lower portion of the fourth via; and
a sixth wiring on and in contact with the fourth via, the sixth wiring extending in the second direction, wherein the sixth wiring includes the third conductive material.

18. The wiring structure of claim 17, wherein:
each of the first wiring and the lower portion of the first via has a first width in the second direction,
each of the second wiring and the second via has a second width in the second direction, wherein the second width is greater than the first width,
each of the third wiring and the lower portion of the fourth via has a third width in the second direction, wherein the third width is greater than the second width,
the upper portion of the first via has a fourth width in the second direction, wherein the fourth width is greater than the first width, and
the third via has a fifth width in the second direction, wherein the fifth width is greater than the second and fourth widths.

19. The wiring structure of claim 18, wherein:
the first to third hard masks have the first to third widths in the second direction, respectively,
a sidewall of the first hard mask extending in the first direction is aligned, in a third direction perpendicular to the upper surface of the substrate, with a sidewall of the lower portion of the first via extending in the first direction,
a sidewall of the second hard mask extending in the first direction is aligned, in the third direction, with a sidewall of the second via extending in the first direction, and
a sidewall of the third hard mask extending in the first direction is aligned, in the third direction, with a sidewall of the fourth via extending in the first direction.

20. The wiring structure of claim 17, wherein:
the second conductive material includes ruthenium or iridium, and
the third conductive material includes copper.
